(19) United States
(12) Patent Application Publication
(10) Pub. No.: US 2023/0387039 A1
(43) Pub. Date: Nov. 30, 2023

(54) SEMICONDCUTOR PACKAGES AND METHODS OF FORMING THEREOF

(71) Applicant: Taiwan Semiconductor Manufacturing Co., Ltd., Hsinchu (TW)

(72) Inventors: Sung-Yueh Wu, Hsinchu (TW); Jen-Chun Liao, Taipei (TW); Mao-Yen Chang, Kaohsiung (TW); Yu-Chia Lai, Zhunan Township (TW); Chien Ling Hwang, Hsinchu (TW); Ching-Hua Hsieh, Hsinchu (TW)

(21) Appl. No.: 17/881,128

(22) Filed: Aug. 4, 2022

Related U.S. Application Data
(60) Provisional application No. 63/365,353, filed on May 26, 2022.

(51) Int. Cl. H01L 23/00; H01L 23/31; H01L 23/498; H01L 23/367; H01L 23/552; H01L 21/56; H01L 21/48

(52) U.S. Cl. CPC H01L 23/562; H01L 23/3107; H01L 23/49822; H01L 23/49838; H01L 23/367; H01L 23/552; H01L 21/56; H01L 21/4857

(57) ABSTRACT

A semiconductor package includes a first package component comprising: an integrated circuit die; an encapsulant surrounding the integrated circuit die; and a fan-out structure electrically connected to the integrated circuit die, wherein a first opening extends completely through the fan-out structure and at least partially through the encapsulant in a cross-sectional view, and wherein the encapsulant at least completely surrounds the first opening in a top-down view. The semiconductor package further includes a package substrate bonded to the first package component.

### PRIORITY CLAIM AND CROSS-REFERENCE

This application claims the benefit of U.S. Provisional Application No. 63/365,353, filed on May 26, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 14, 15A, 15B, 15C, 15D, 15E, 15F, 15G, 15H, 15I, 15J, 15K, 15L, 15M, 15N, 15O, 15P, 15Q, 15R, 15S, 15T, 16A, 16B, 17A, 17B, 17C, 18A, and 18B illustrate cross-sectional and top-down views of manufacturing device packages according to some embodiments.

FIGS. 19, 20A, 20B, 20C, 20D, 20E, and 20F illustrate cross-sectional views of manufacturing device packages according to some embodiments.

FIGS. 21, 22, 23A, 23B, 23C, 23D, 23E, and 23F illustrate cross-sectional views of manufacturing device packages according to some embodiments.

FIGS. 24, 25A, 25B, 25C, 25D, 25E, and 25F illustrate cross-sectional views of manufacturing device packages according to some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, one or more integrated circuit dies are electrically connected by a fan-out structure (e.g., a redistribution structure, an interposer, a local silicon interconnect (LSI), or the like), and the integrated circuit dies may be encapsulated for further packaging with other package components (e.g., a package substrate or the like). One or more openings may be formed in the molding compound and/or the fan-out structure. The inclusion of the openings may provide the following, non-limiting advantages. For example, the opening may facilitate thermal dissipation of heat away from the semiconductor dies through the openings. As another example, the openings may facilitate the insertion of one or more advantageous components, such as a thermal dissipation feature, electromagnetic interference (EMI) shields, or the like. Further, the openings may facilitate the insertion of structural support elements (e.g., braces or the like) in the package. As a result, improved package performance and/or manufacturing ease may be achieved.

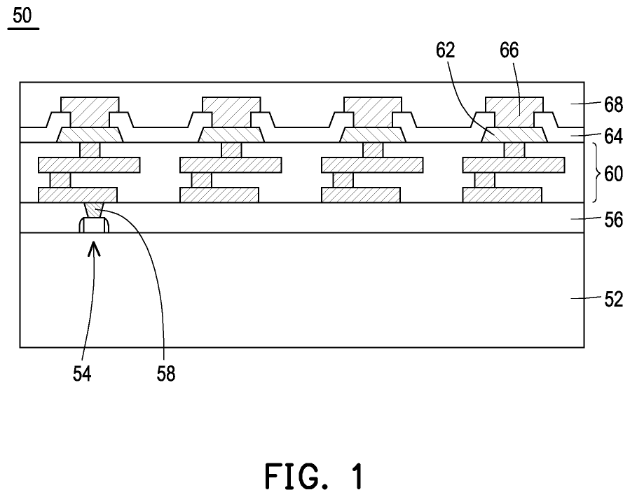

FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. Source/drain region(s) may refer to a source or a drain, individually or collectively dependent upon the context. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

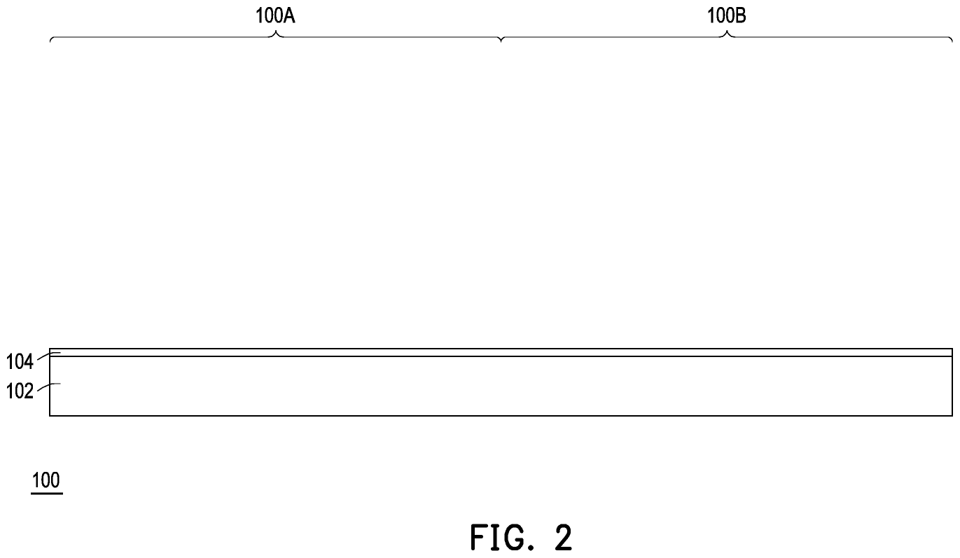

FIGS. 2 through 15T illustrate cross-sectional views of intermediate steps during a process for forming a first package component 100, in accordance with some embodiments. A first package region 100A and a second package region 100B are illustrated, and one or more of the integrated circuit dies 50 are packaged to form an integrated circuit package in each of the package regions 100A and 100B. The integrated circuit packages may also be referred to as integrated fan-out (InFO) packages.

In FIG. 2, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

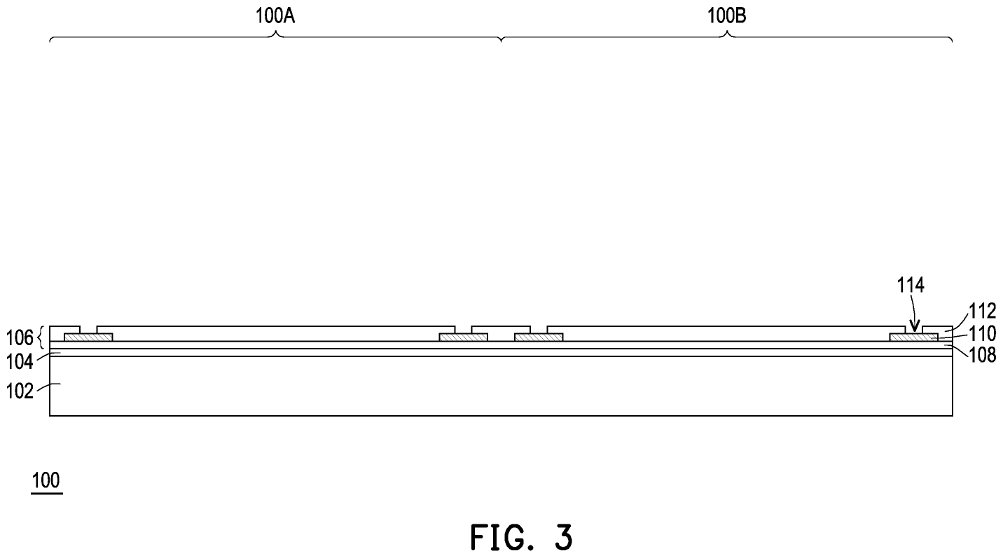

In FIG. 3, a back-side redistribution structure 106 may be formed on the release layer 104. In the embodiment shown, the back-side redistribution structure 106 includes a dielectric layer 108, a metallization pattern 110 (sometimes referred to as redistribution layers or redistribution lines), and a dielectric layer 112. The back-side redistribution structure 106 is optional. In some embodiments, a dielectric layer without metallization patterns is formed on the release layer 104 in lieu of the back-side redistribution structure 106.

The dielectric layer 108 may be formed on the release layer 104. The bottom surface of the dielectric layer 108 may be in contact with the top surface of the release layer 104. In some embodiments, the dielectric layer 108 is formed of a polymer, such as polybenzoxazole (PBO), polyimide, benzocyclobutene (BCB), or the like. In other embodiments, the dielectric layer 108 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 108 may be formed by any acceptable deposition process, such as spin coating, CVD, laminating, the like, or a combination thereof.

The metallization pattern 110 may be formed on the dielectric layer 108. As an example to form metallization pattern 110, a seed layer is formed over the dielectric layer 108. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern 110. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110.

The dielectric layer 112 may be formed on the metallization pattern 110 and the dielectric layer 108. In some embodiments, the dielectric layer 112 is formed of a polymer, which may be a photo-sensitive material such as PBO, polyimide, BCB, or the like, that may be patterned using a lithography mask. In other embodiments, the dielectric layer 112 is formed of a nitride such as silicon nitride; an oxide such as silicon oxide, PSG, BSG, BPSG; or the like. The dielectric layer 112 may be formed by spin coating, lamination, CVD, the like, or a combination thereof. The dielectric layer 112 is then patterned to form openings 114 exposing portions of the metallization pattern 110. The patterning may be formed by an acceptable process, such as by exposing the dielectric layer 112 to light when the dielectric layer 112 is a photo-sensitive material or by etching using, for example, an anisotropic etch. If the dielectric layer 112 is a photo-sensitive material, the dielectric layer 112 can be developed after the exposure.

FIG. 3 illustrates a redistribution structure 106 having a single metallization pattern 110 for illustrative purposes. In some embodiments, the back-side redistribution structure 106 may include any number of dielectric layers and metallization patterns. If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in the opening of the underlying dielectric layer, thereby interconnecting and electrically coupling various conductive lines.

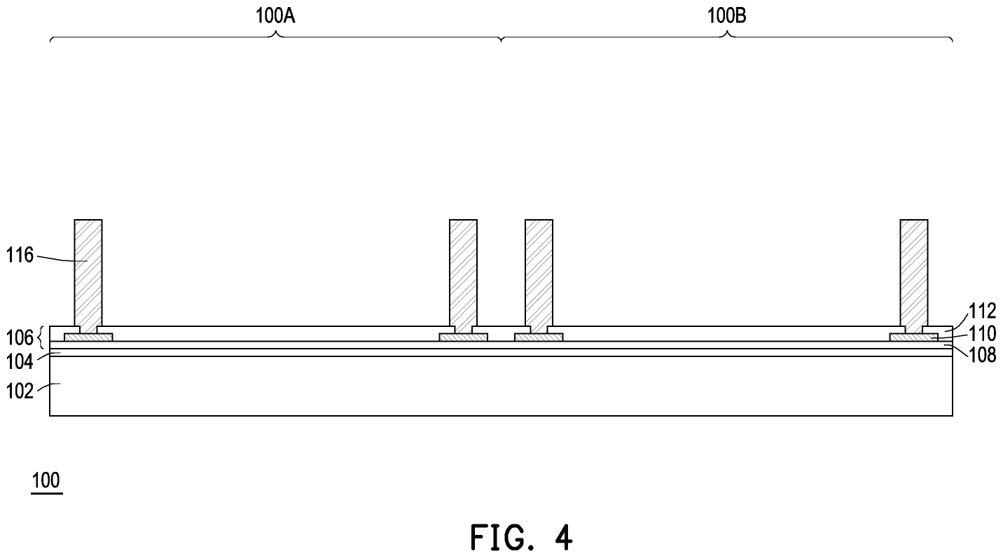

In FIG. 4, through vias 116 are formed in the openings 114 and extending away from the topmost dielectric layer of the back-side redistribution structure 106 (e.g., the dielectric layer 112). As an example to form the through vias 116, a seed layer (not shown) is formed over the back-side redistribution structure 106, e.g., on the dielectric layer 112 and portions of the metallization pattern 110 exposed by the openings 114. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 116.

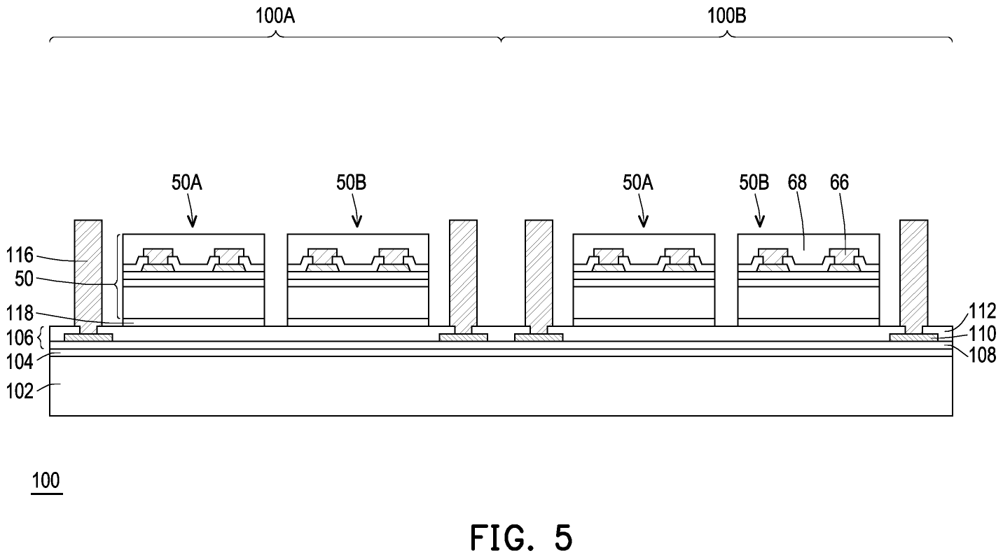

In FIG. 5, integrated circuit dies 50 (e.g., a first integrated circuit die 50A and a second integrated circuit die 50B) are adhered to the dielectric layer 112 by an adhesive 118. A desired type and quantity of integrated circuit dies 50 are adhered in each of the package regions 100A and 100B. In the embodiment shown, multiple integrated circuit dies 50 are adhered adjacent one another, including the first integrated circuit die 50A and the second integrated circuit die 50B in each of the first package region 100A and the second package region 100B. The first integrated circuit die 50A may be a logic device, such as a central processing unit (CPU), a graphics processing unit (GPU), a system-on-a-chip (SoC), a microcontroller, or the like. The second integrated circuit die 50B may be a memory device, such as a dynamic random access memory (DRAM) die, a static random access memory (SRAM) die, a hybrid memory cube (HMC) module, a high bandwidth memory (HBM) module, or the like. In some embodiments, the integrated circuit dies 50A and 50B may be the same type of dies, such as SoC dies. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas). The space available for the through vias 116 in the first package region 100A and the second package region 100B may be limited, particularly when the integrated circuit dies 50 include devices with a large footprint, such as SoCs. Use of the back-side redistribution structure 106 allows for an improved interconnect arrangement when the first package region 100A and the second package region 100B have limited space available for the through vias 116.

The adhesive 118 is on back-sides of the integrated circuit dies 50 and adheres the integrated circuit dies 50 to the back-side redistribution structure 106, such as to the dielectric layer 112. The adhesive 118 may be any suitable adhesive, epoxy, die attach film (DAF), or the like. The adhesive 118 may be applied to back-sides of the integrated circuit dies 50, may be applied over the surface of the carrier substrate 102 if no back-side redistribution structure 106 is utilized, or may be applied to an upper surface of the back-side redistribution structure 106 if applicable. For example, the adhesive 118 may be applied to the back-sides of the integrated circuit dies 50 before singulating to separate the integrated circuit dies 50.

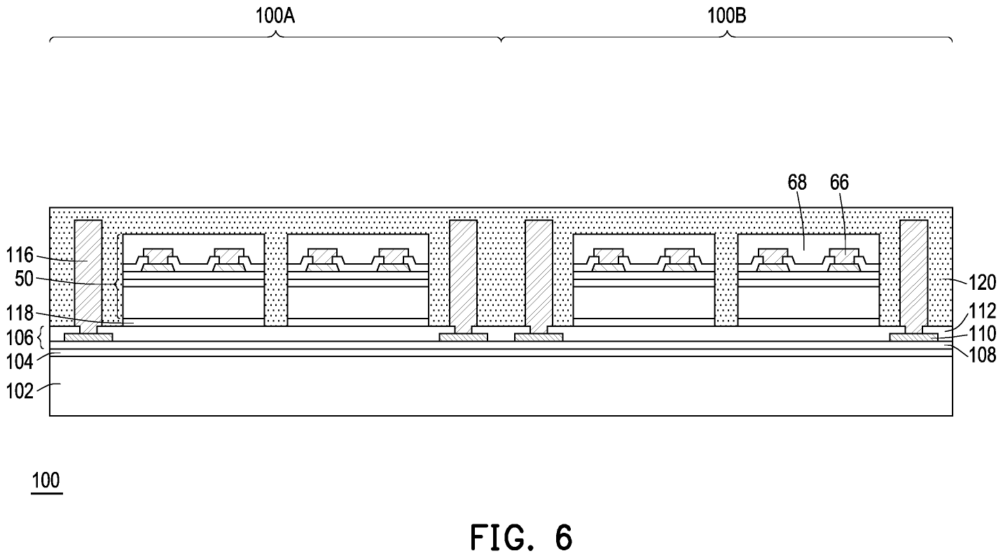

In FIG. 6, an encapsulant 120 is formed on and around the various components. After formation, the encapsulant 120 encapsulates the through vias 116 and integrated circuit dies 50. The encapsulant 120 may be a molding compound, epoxy, or the like. The encapsulant 120 may be applied by compression molding, transfer molding, or the like, and may be formed over the carrier substrate 102 such that the through vias 116 and/or the integrated circuit dies 50 are buried or covered. The encapsulant 120 is further formed in gap regions between the integrated circuit dies 50. The encapsulant 120 may be applied in liquid or semi-liquid form and then subsequently cured.

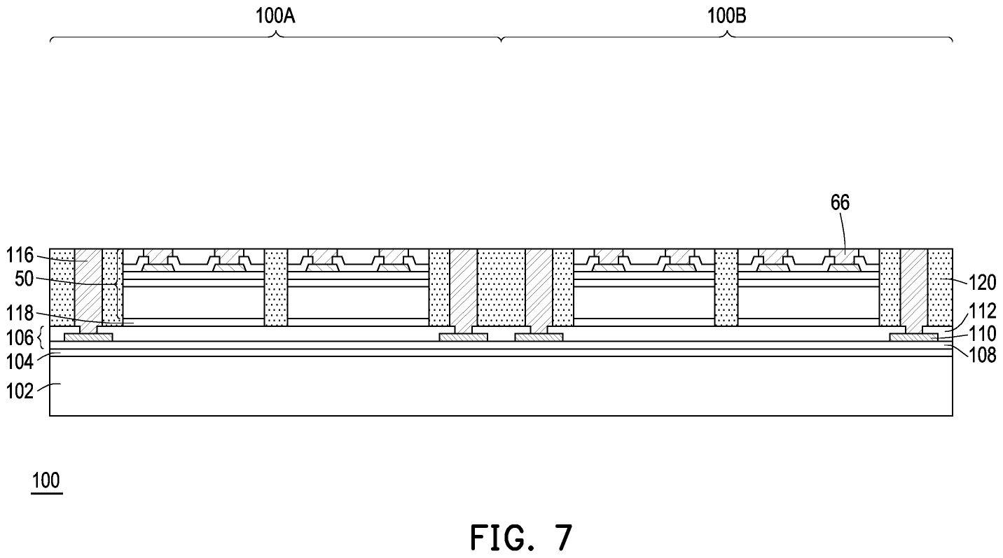

In FIG. 7, a planarization process is performed on the encapsulant 120 to expose the through vias 116 and the die connectors 66. The planarization process may also remove material of the through vias 116, dielectric layer 68, and/or die connectors 66 until the die connectors 66 and through vias 116 are exposed. Top surfaces of the through vias 116, die connectors 66, dielectric layer 68, and encapsulant 120 are substantially coplanar after the planarization process within process variations. The planarization process may be, for example, a chemical-mechanical polish (CMP), a grinding process, or the like. In some embodiments, the planarization may be omitted, for example, if the through vias 116 and/or die connectors 66 are already exposed.

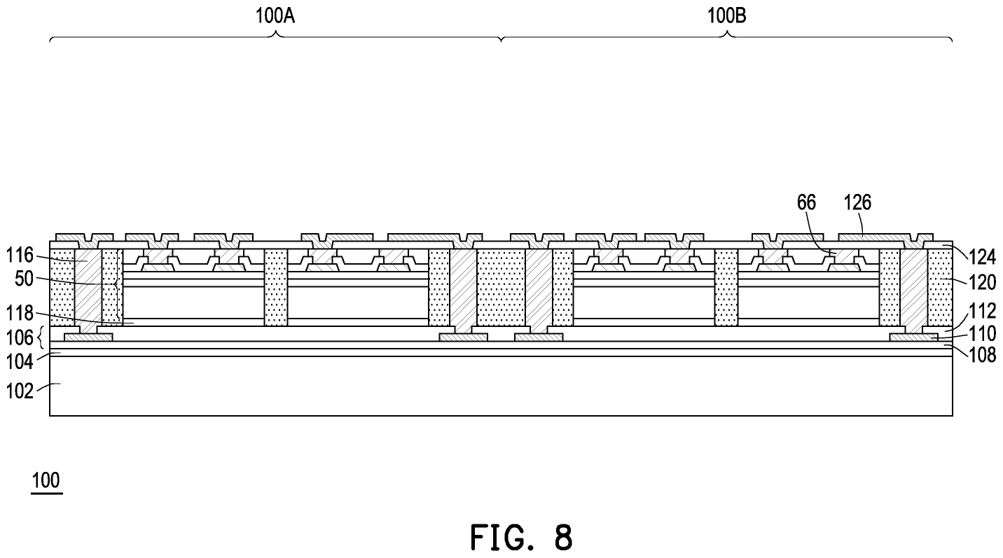

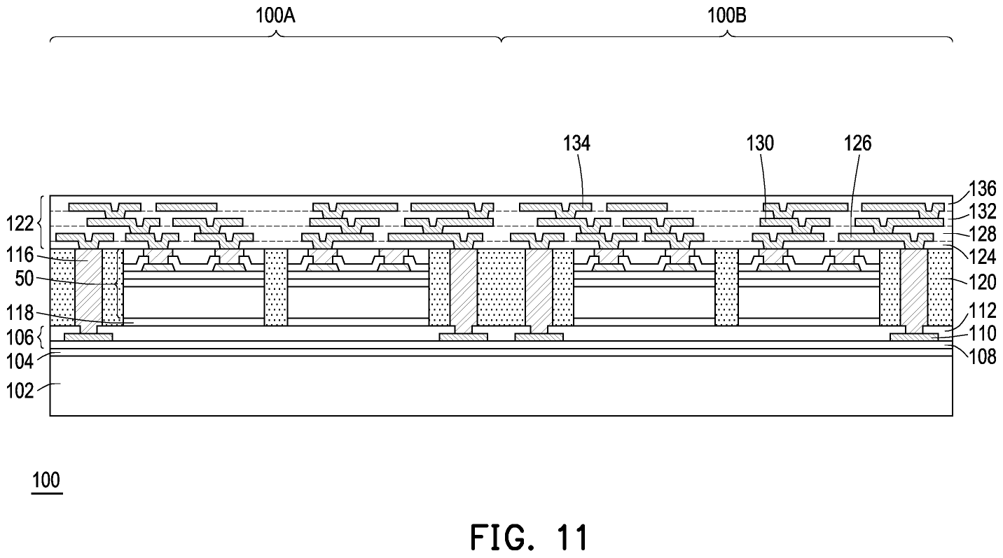

In FIGS. 8 through 11, a front-side redistribution structure 122 (see FIG. 11) is formed over the encapsulant 120, through vias 116, and integrated circuit dies 50. The front-side redistribution structure 122 includes dielectric layers 124, 128, 132, and 136; and metallization patterns 126, 130, and 134. The metallization patterns may also be referred to as redistribution layers or redistribution lines. The front-side redistribution structure 122 is shown as an example having three layers of metallization patterns. More or fewer dielectric layers and metallization patterns may be formed in the front-side redistribution structure 122. If fewer dielectric layers and metallization patterns are to be formed, steps and process discussed below may be omitted. If more dielectric layers and metallization patterns are to be formed, steps and processes discussed below may be repeated.

In FIG. 8, the dielectric layer 124 is deposited on the encapsulant 120, through vias 116, and die connectors 66. In some embodiments, the dielectric layer 124 is formed of a photo-sensitive material such as PBO, polyimide, BCB, or the like, which may be patterned using a lithography mask. The dielectric layer 124 may be formed by spin coating, lamination, CVD, the like, or a combination thereof. The dielectric layer 124 is then patterned. The patterning forms openings exposing portions of the through vias 116 and the die connectors 66. The patterning may be by an acceptable process, such as by exposing and developing the dielectric layer 124 to light when the dielectric layer 124 is a photo-sensitive material or by etching using, for example, an anisotropic etch.

The metallization pattern 126 is then formed. The metallization pattern 126 includes conductive elements extending along the major surface of the dielectric layer 124 and extending through the dielectric layer 124 to physically and electrically couple to the through vias 116 and the integrated circuit dies 50. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 126. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

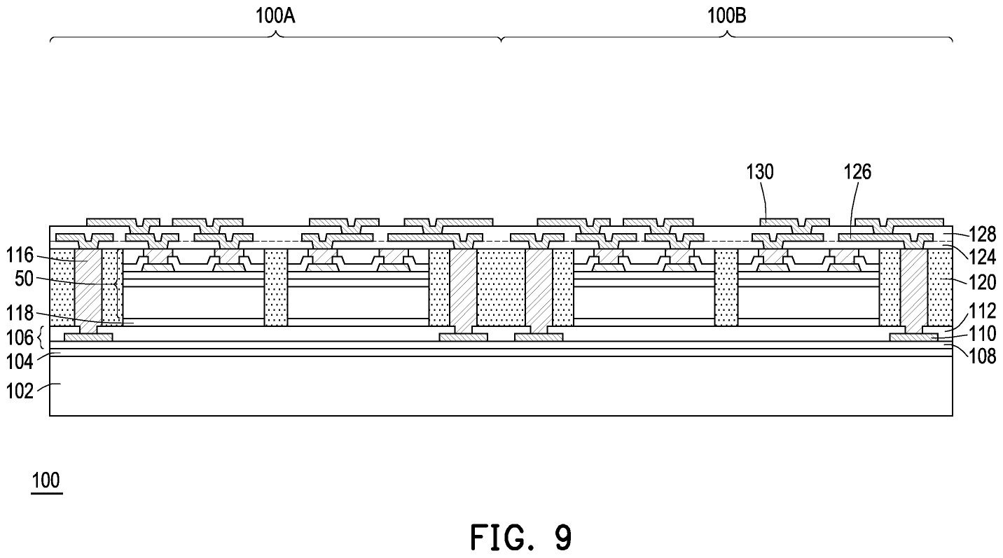

In FIG. 9, the dielectric layer 128 is deposited on the metallization pattern 126 and the dielectric layer 124. The dielectric layer 128 may be formed in a manner similar to the dielectric layer 124, and may be formed of a similar material as the dielectric layer 124.

The metallization pattern 130 is then formed. The metallization pattern 130 includes portions on and extending along the major surface of the dielectric layer 128. The metallization pattern 130 further includes portions extending through the dielectric layer 128 to physically and electrically couple the metallization pattern 126. The metallization pattern 130 may be formed in a similar manner and of a similar material as the metallization pattern 126. In some embodiments, the metallization pattern 130 has a different size than the metallization pattern 126. For example, the conductive lines and/or vias of the metallization pattern 130 may be wider or thicker than the conductive lines and/or vias of the metallization pattern 126. Further, the metallization pattern 130 may be formed to a greater pitch than the metallization pattern 126.

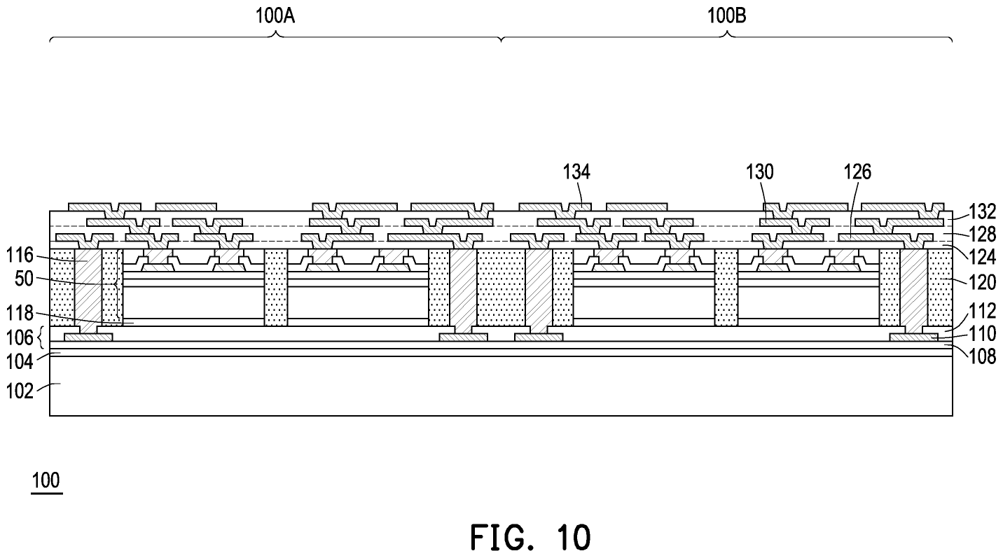

In FIG. 10, the dielectric layer 132 is deposited on the metallization pattern 130 and the dielectric layer 128. The dielectric layer 132 may be formed in a manner similar to the dielectric layer 124, and may be formed of a similar material as the dielectric layer 124.

The metallization pattern 134 is then formed. The metallization pattern 134 includes portions on and extending along the major surface of the dielectric layer 132. The metallization pattern 134 further includes portions extending through the dielectric layer 132 to physically and electrically couple the metallization pattern 130. The metallization pattern 134 may be formed in a similar manner and of a similar material as the metallization pattern 126. The metallization pattern 134 is the topmost metallization pattern of the front-side redistribution structure 122. As such, all of the intermediate metallization patterns of the front-side redistribution structure 122 (e.g., the metallization patterns 126 and 130) are disposed between the metallization pattern 134 and the integrated circuit dies 50. In some embodiments, the metallization pattern 134 has a different size than the metallization patterns 126 and 130. For example, the conductive lines and/or vias of the metallization pattern 134 may be wider or thicker than the conductive lines and/or vias of the metallization patterns 126 and 130. Further, the metallization pattern 134 may be formed to a greater pitch than the metallization pattern 130.

In FIG. 11, the dielectric layer 136 is deposited on the metallization pattern 134 and the dielectric layer 132. The dielectric layer 136 may be formed in a manner similar to the dielectric layer 124, and may be formed of the same material as the dielectric layer 124. The dielectric layer 136 is the topmost dielectric layer of the front-side redistribution structure 122. As such, all of the metallization patterns of the front-side redistribution structure 122 (e.g., the metallization patterns 126, 130, and 134) are disposed between the dielectric layer 136 and the integrated circuit dies 50. Further, all of the intermediate dielectric layers of the front-side redistribution structure 122 (e.g., the dielectric layers 124, 128, 132) are disposed between the dielectric layer 136 and the integrated circuit dies 50.

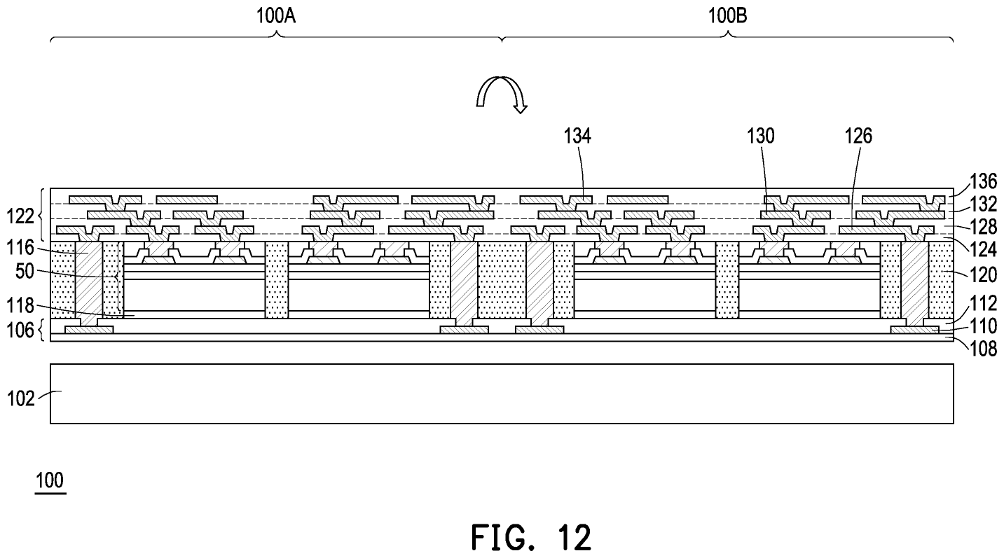

In FIG. 12, a carrier substrate de-bonding is performed to detach (or “de-bond”) the carrier substrate 102 from the back-side redistribution structure 106, e.g., the dielectric layer 108. In accordance with some embodiments, the de-bonding includes projecting a light such as a laser light or an UV light on the release layer 104 so that the release layer 104 decomposes under the heat of the light and the carrier substrate 102 can be removed.

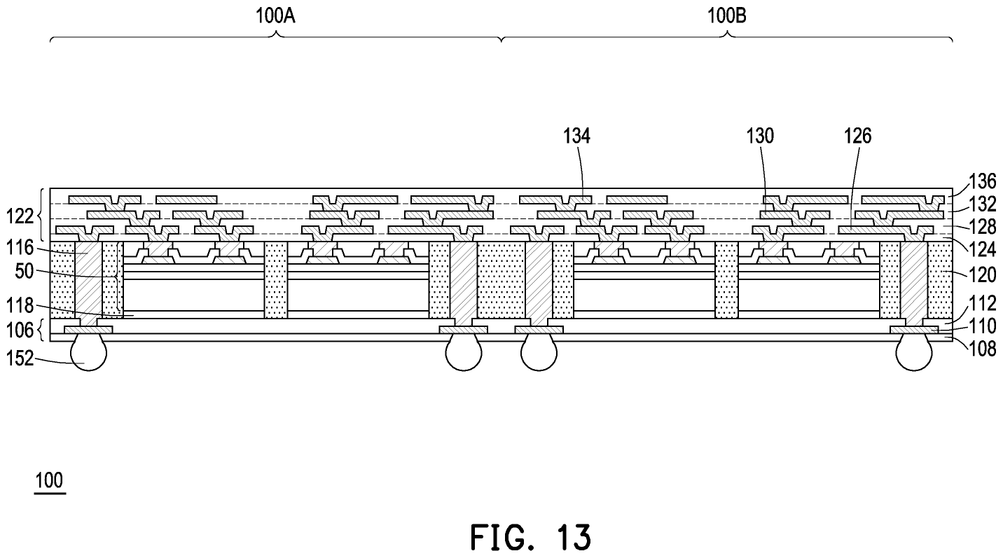

In FIG. 13, conductive connectors 152 are formed extending through the dielectric layer 108 to contact the metallization pattern 110. Openings are formed through the dielectric layer 108 to expose portions of the metallization pattern 110. The openings may be formed, for example, using laser drilling, etching, or the like. The conductive connectors 152 are formed in the openings. In some embodiments, the conductive connectors 152 comprise flux and are formed in a flux dipping process. In some embodiments, the conductive connectors 152 comprise a conductive paste such as solder paste, silver paste, or the like, and are dispensed in a printing process. In some embodiments, the conductive connectors 152 are formed in a manner similar to the conductive connectors 150, and may be formed of a similar material as the conductive connectors 150.

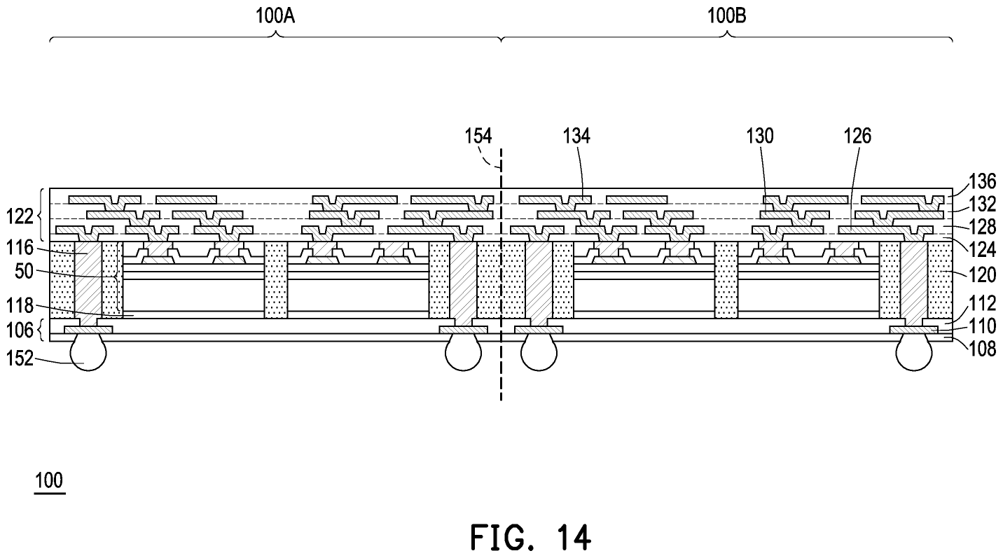

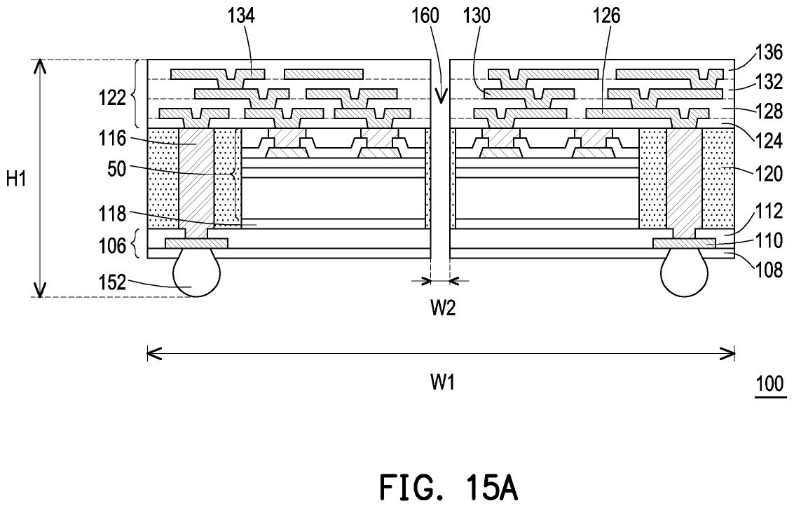

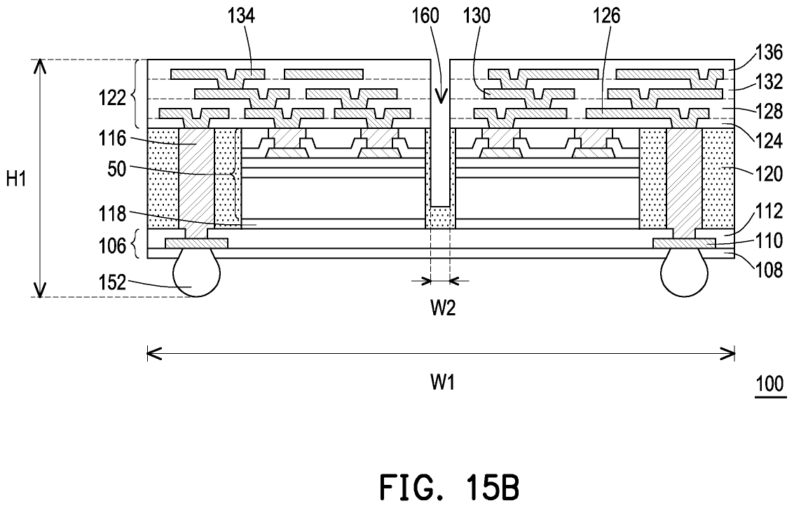

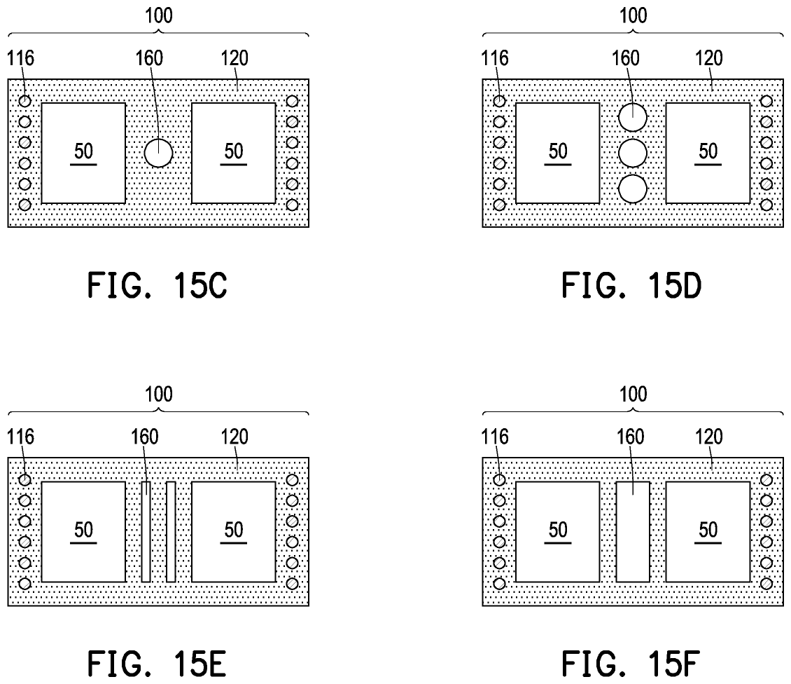

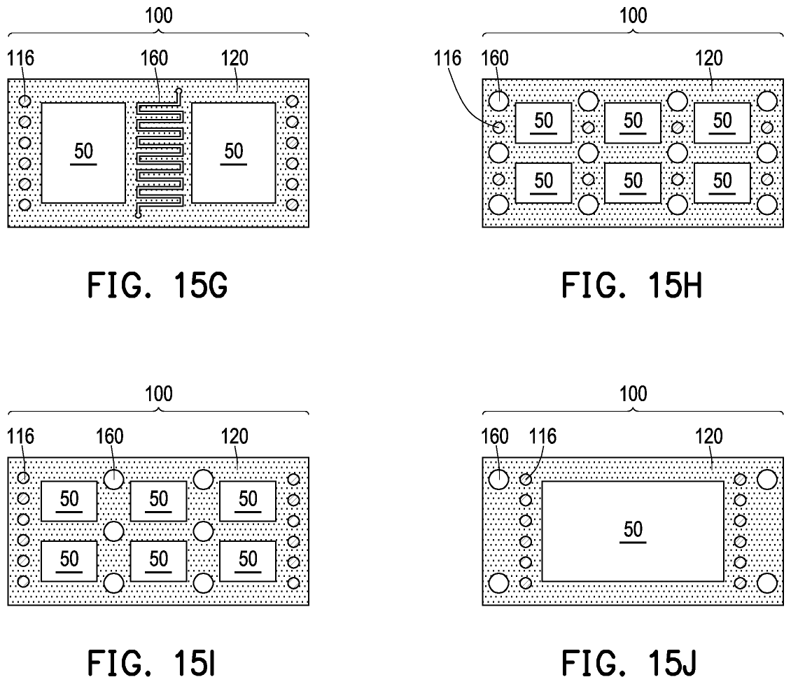

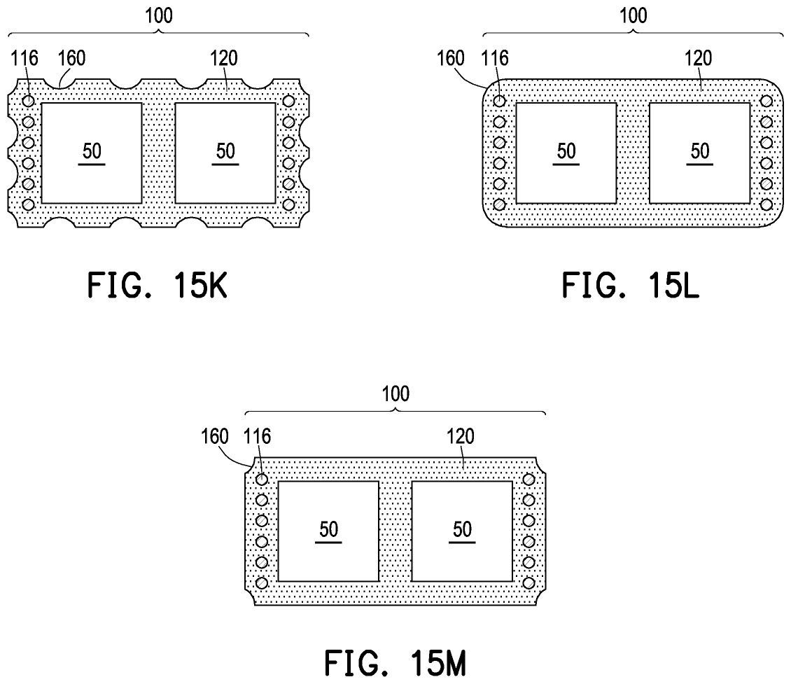

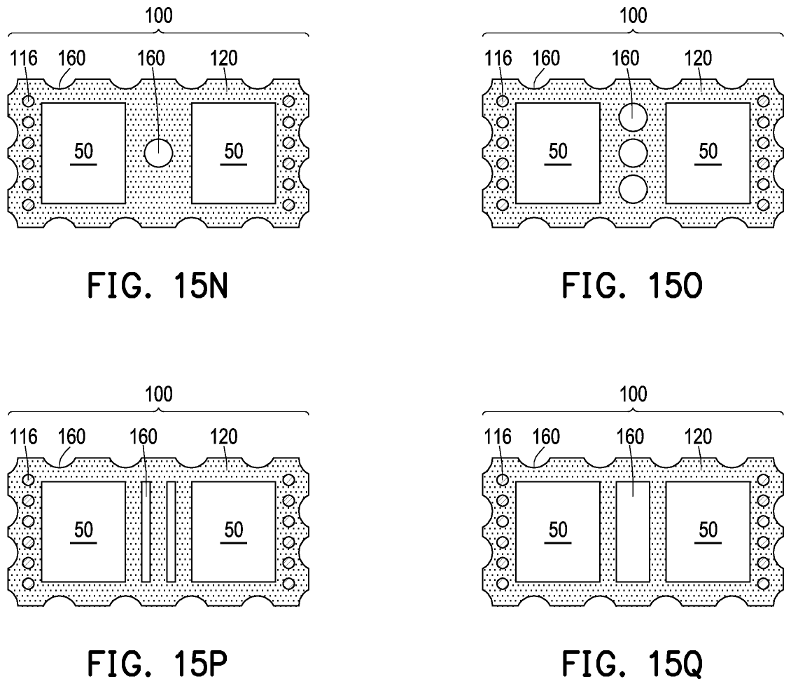

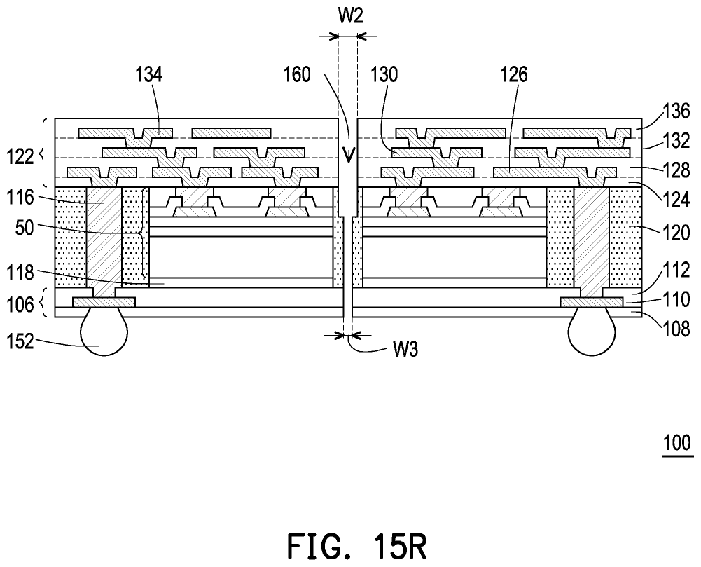

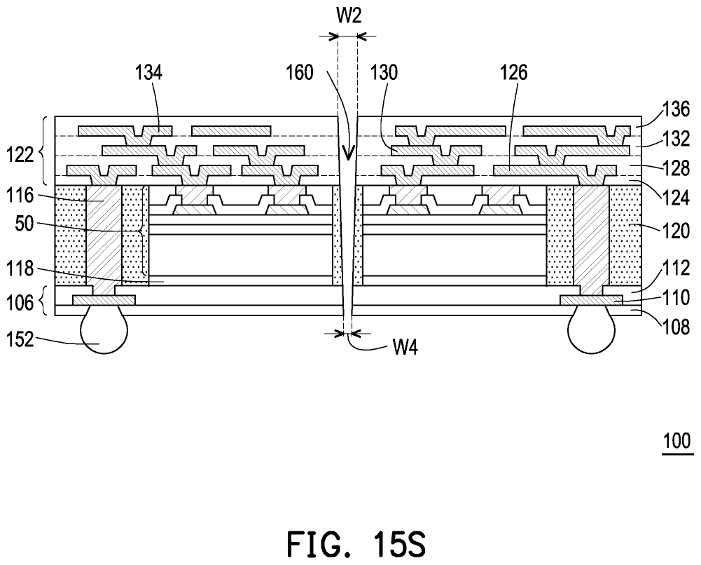

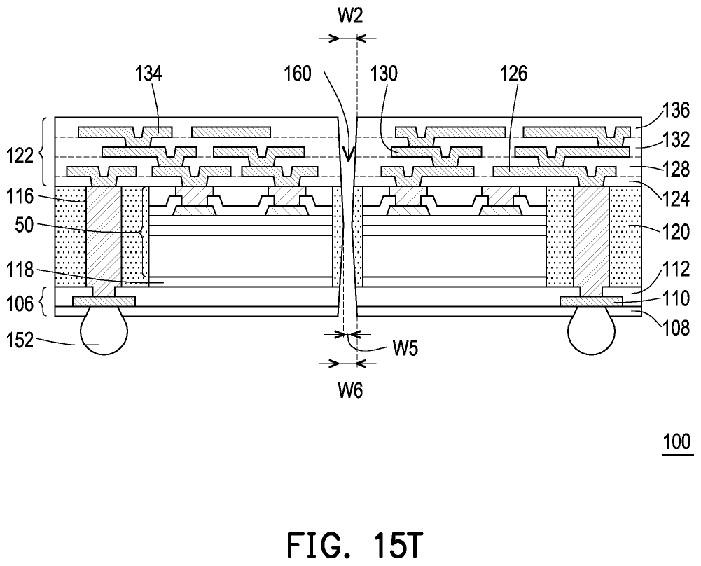

In FIG. 14, a singulation process is performed by sawing along scribe line regions, e.g., between the first package region 100A and the second package region 100B. The sawing singulates the first package region 100A from the second package region 100B. The resulting, singulated first package component 100 is from one of the first package region 100A or the second package region 100B. The singulation process may include any suitable process, such as, laser ablation, mechanical drilling, mechanical grinding, the like, or combinations thereof. As a result of the singulation process, each of the first package components 100 may have an overall width W1 (e.g., measured between outer sidewalls) in a range of 5 mm to 300 mm (see FIGS. 15A and 15B). Each of the first package components 100 may further have an overall height H1 in a range of 0.1 mm to 300 mm (see FIGS. 15A and 15B).

In FIGS. 15A through 15T, one or more openings 160 may be formed in each of the singulated, package components 100. Referring first to FIG. 15A, the openings 160 may be formed to extend completely through the first package component 100, such as through the front-side redistribution structure 122, the encapsulant 120, and the backside redistribution structure 106. The openings 160 may be formed using any suitable process, such as by laser machining, mechanical drilling/routing, plasma etching/bombardment, or chemical etching. In embodiments where a chemical etching process is used to form the openings 160, a sacrificial material (not illustrated) may be formed in the front-side redistribution structure 122, the encapsulant 120, and the backside redistribution structure 106. A location, size, and shape of the sacrificial material may correspond to a location, size, and shape of the openings 160, and the sacrificial material may be formed of a material that can be selectively etched relative to a material of the encapsulant 120 and material(s) of the dielectric layers 108, 112, 124, 128, 132, and 136. For example, the sacrificial material may comprise a conductive material, such as copper or the like that is formed by one or more plating processes (e.g., along similar lines as the metallization patterns in the redistribution structure 106, 122 and the through vias 116). In such embodiments, the chemical etching may use a chemical that selectively removes the sacrificial material without significantly removing the encapsulant 120 or the dielectric layers 108, 112, 124, 128, 132, and 136.

The openings 160 may facilitate heat transfer away from the integrated circuit dies 50 by increasing a number of heat dissipation surfaces in the first package component 100. For example, the sidewalls of the openings 160 may provide additional heat dissipation surfaces in the first package component 100. In some embodiments, the openings 160 may further facilitate process integration by allowing subsequent features to be inserted in the openings 160. For example, in some embodiments, heat transfer structures, EMI shielding structures, mechanical braces, or the like may be subsequently inserted in the openings 160 for improved structural integrity and/or performance in the resulting semiconductor package. The openings 160 may each have a maximum width W2 that is in a range of 0.05 mm to 10 mm.

FIG. 15A illustrates the opening 160 as extending completely through the first package component 100. In other embodiments, the openings 160 may only extend partially through the first package component 100. For example, FIG. 15B illustrates an embodiment where the openings 160 extends through the front-side redistribution structure 122 and partially into the encapsulant 120. However, a portion of the encapsulant 120 may remain under the openings 160, and the openings 160 may not extend into the backside redistribution structure 106. In other embodiments, the openings 160 may extend to different depths in first package component 100.

FIGS. 15C through 15Q illustrate top-down views of varying configurations of the openings 160 in embodiment first package components 100. For ease of reference, the front-side redistribution structure 122 is omitted from these figures.

The openings 160 may have any suitable shape. For example, referring to FIGS. 15C and 15D, the openings 160 may have a round (e.g., circular) shape in a top-down view, and the openings 160 may be disposed between adjacent ones of the integrated circuit dies 50. The first package components 100 may comprise any number of round openings 160, such as a singular opening 160 (see FIG. 15C) or multiple openings 160 (see FIG. 15D).

In other embodiments, referring to FIG. 15E and 15F, the openings 160 may have a rectangular shape in a top-down view, and the openings 160 may be disposed between adjacent ones of the integrated circuit dies 50. The first package components 100 may comprise any number of rectangular openings 160, such as a singular opening 160 (see FIG. 15E) or multiple openings 160 (see FIG. 15F).

In other embodiments, referring to FIG. 15G, the openings 160 may have an irregular shape. For example, the openings 160 may be configured as a microchannel with a zig-zagging channel shape that is disposed between adjacent ones of the integrated circuit dies 50. Other shapes for the openings 160 are also possible.

FIGS. 15C through 15G illustrate a first package component 100 with two integrated circuit dies 50. In other embodiments, the openings 160 may be integrated with a different number of integrated circuit dies 50. For example, the first package component 100 may comprise a greater number of integrated circuit dies 50 (e.g., six) as illustrated by FIGS. 15H and 15I. The openings 160 may be disposed at regular intervals between adjacent ones of the integrated circuit dies 50. Further, the openings 160 may be integrated with the through vias 116 (see FIG. 15H) or the openings 160 may be disposed in separate columns than the through vias 116 (see FIG. 15I). As another example, the first package component 100 may comprise a singular integrated circuit die 50, and the openings 160 may be disposed in corner regions of the encapsulant 120. This configuration is illustrated in FIG. 15J. Other configurations are also possible.

In FIGS. 15C through 15J, each of the openings 160 are disposed in the interior of the first package component 100 and are completely surrounded by the first package component 100 in a top down view. For example, each of the openings 160 may be encircled by a material of at least the encapsulant 120 in a top down view. In other embodiments, the openings 160 may be disposed at edges of the first package component 100 such that the first package component 100 only partially surrounds the openings 160. In such embodiments, the first package component 100 may have varying widths in a top down view. FIGS. 15K through 15M illustrate embodiments where the openings 160 are disposed at edges of the package components 100. In the embodiments of FIGS. 15K and 15M, the openings 160 may be formed concurrently with the singulation process described above with respect to FIG. 14. Alternatively, the edge openings 160 may be formed after the singulation process first defines a substantially rectangular first package component 100 using the processes described above (e.g., laser machining, mechanical drilling/routing, plasma etching/bombardment, or chemical etching). In FIG. 15K, the openings 160 are disposed at regular intervals along an entire outer perimeter of the first package component 100 to achieve a scalloped edge shape. In FIGS. 15L and 15M, the openings 160 may be patterned only in corner regions of the first package component 100 to achieve rounded corners. FIG. 15L illustrate openings 160 that are convex in shape while FIG. 15M illustrates openings 160 that are concave in shape.

In other embodiments, edge openings 160 (e.g., as illustrated by FIGS. 15K through 15M) may be combined with interior openings 160 (e.g., as illustrated by FIGS. 15C through 15L). FIGS. 15N through 15Q illustrates embodiments where openings 160 are disposed at edges and an interior of the first package component 100. Specifically, FIG. 15N illustrates the first package component 100 with a scalloped edge (e.g., multiple edge openings 160) and a singular, round opening 160 in an interior of the encapsulant 120. FIG. 15O illustrates the first package component 100 with a scalloped edge (e.g., multiple edge openings 160) and multiple, round openings 160 in an interior of the encapsulant 120. FIG. 15P illustrates the first package component 100 with a scalloped edge (e.g., multiple edge openings 160) and a singular, rectangular opening 160 in an interior of the encapsulant 120. FIG. 15Q illustrates the first package component 100 with a scalloped edge (e.g., multiple edge openings 160) and multiple, rectangular openings 160 in an interior of the encapsulant 120. Other combinations are also possible.

In FIGS. 15A and 15B, the openings 160 has a substantially uniform width W2 throughout in a cross-sectional view. In other embodiments, the openings 160 may have varied widths in a cross-sectional view. For example, FIG. 15R illustrates an embodiment where each of the openings 160 have an upper portion with the width W2 described above and further has a lower portion with a width W3. The width W3 is less than the width W2, and a discrete step is disposed in the openings 160. FIG. 15S illustrates another embodiment, where each of the openings 160 have varied widths. Specifically, each of the openings 160 may be tapered with slanted sidewalls that transitions from the width W2 described above to a smaller, width W4. The width W2 may be disposed at a top surface of the front-side redistribution structure 122, and the width W4 may be disposed at a bottom surface of the backside redistribution structure 106. FIG. 15T illustrates another embodiment, where each of the openings 160 have varied widths. Specifically, each of the openings 160 may be tapered with slanted sidewalls that transitions from the width W2 described above to a smaller, width W5 and back to a larger width W6. The width W2 may be disposed at a top surface of the front-side redistribution structure 122; the width W5 may be disposed at a midpoint in the encapsulant 120, and the width W6 may be disposed at a bottom surface of the backside redistribution structure 106. The width W6 may or may not be equal to the width W2.

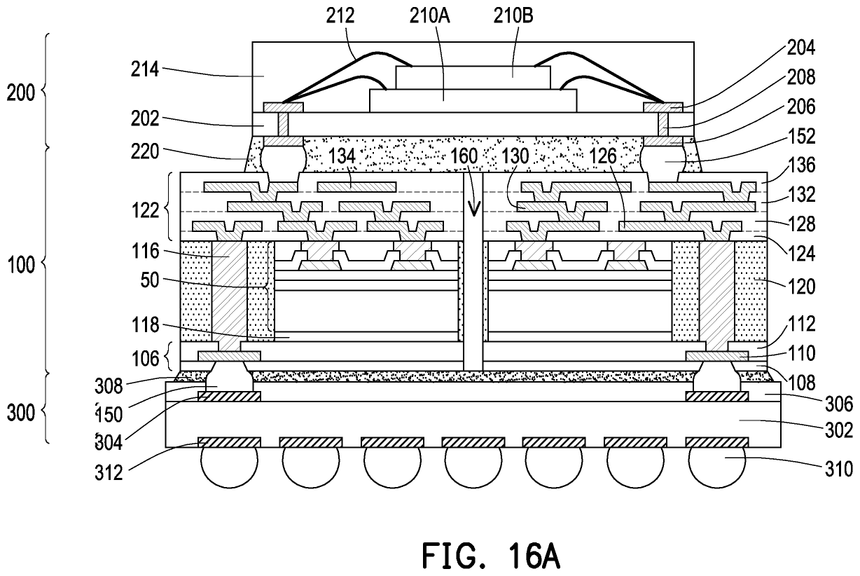

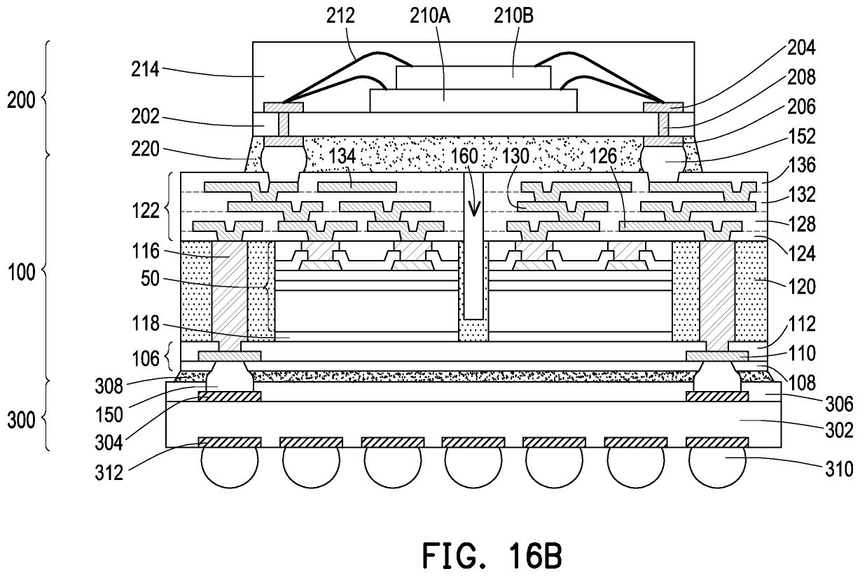

FIGS. 16A and 16B illustrate the formation and implementation of device stacks, in accordance with some embodiments. The device stacks are formed from the integrated circuit packages formed in the first package component 100. The device stacks may also be referred to as package-on-package (PoP) structures. FIG. 16A corresponds to the embodiments of FIG. 15A where the opening 160 extends completely through the first package component 100, and FIG. 16B corresponds to the embodiments of FIG. 15B where the opening 160 extends partially through the first package component 100. It should be understood that the description of FIGS. 16A and 16B may be applied to any of the embodiments of FIGS. 15C through 15T described above.

In FIGS. 16A and 16B, second package components 200 are coupled to the first package component 100. The second package components 200 include, for example, a substrate 202 and one or more stacked dies 210 (e.g., 210A and 210B) coupled to the substrate 202. Although one set of stacked dies 210 (210A and 210B) is illustrated, in other embodiments, a plurality of stacked dies 210 (each having one or more stacked dies) may be disposed side-by-side coupled to a same surface of the substrate 202. The substrate 202 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate 202 may be a silicon-on-insulator (SOI) substrate. Generally, an SOI substrate includes a layer of a semiconductor material such as epitaxial silicon, germanium, silicon germanium, SOI, silicon germanium on insulator (SGOI), or combinations thereof. The substrate 202 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate 202.

The substrate 202 may include active and passive devices (not shown). A wide variety of devices such as transistors, capacitors, resistors, combinations of these, and the like may be used to generate the structural and functional requirements of the design for the second package components 200. The devices may be formed using any suitable methods.

The substrate 202 may also include metallization layers (not shown) and the conductive vias 208. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate 202 is substantially free of active and passive devices.

The substrate 202 may have bond pads 204 on a first side of the substrate 202 to couple to the stacked dies 210, and bond pads 206 on a second side of the substrate 202, the second side being opposite the first side of the substrate 202, to couple to the conductive connectors 152. In some embodiments, the bond pads 204 and 206 are formed by forming recesses (not shown) into dielectric layers (not shown) on the first and second sides of the substrate 202. The recesses may be formed to allow the bond pads 204 and 206 to be embedded into the dielectric layers. In other embodiments, the recesses are omitted as the bond pads 204 and 206 may be formed on the dielectric layer. In some embodiments, the bond pads 204 and 206 include a thin seed layer (not shown) made of copper, titanium, nickel, gold, palladium, the like, or a combination thereof. The conductive material of the bond pads 204 and 206 may be deposited over the thin seed layer. The conductive material may be formed by an electro-chemical plating process, an electroless plating process, CVD, atomic layer deposition (ALD), PVD, the like, or a combination thereof. In an embodiment, the conductive material of the bond pads 204 and 206 is copper, tungsten, aluminum, silver, gold, the like, or a combination thereof.

In some embodiments, the bond pads 204 and the bond pads 206 are UBMs that include three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the bond pads 204 and 206. Any suitable materials or layers of material that may be used for the bond pads 204 and 206 are fully intended to be included within the scope of the current application. In some embodiments, the conductive vias 208 extend through the substrate 202 and couple at least one of the bond pads 204 to at least one of the bond pads 206.

In the illustrated embodiment, the stacked dies 210 are coupled to the substrate 202 by wire bonds 212, although other connections may be used, such as conductive bumps. In an embodiment, the stacked dies 210 are stacked memory dies. For example, the stacked dies 210 may be memory dies such as low-power (LP) double data rate (DDR) memory modules, such as LPDDR1, LPDDR2, LPDDR3, LPDDR4, or the like memory modules.

The stacked dies 210 and the wire bonds 212 may be encapsulated by a molding material 214. The molding material 214 may be molded on the stacked dies 210 and the wire bonds 212, for example, using compression molding. In some embodiments, the molding material 214 is a molding compound, a polymer, an epoxy, silicon oxide filler material, the like, or a combination thereof. A curing process may be performed to cure the molding material 214; the curing process may be a thermal curing, a UV curing, the like, or a combination thereof.

In some embodiments, the stacked dies 210 and the wire bonds 212 are buried in the molding material 214, and after the curing of the molding material 214, a planarization step, such as a grinding, is performed to remove excess portions of the molding material 214 and provide a substantially planar surface for the second package components 200.

After the second package components 200 are formed, the second package components 200 are mechanically and electrically bonded to the first package component 100 by way of conductive connectors 152 and a metallization pattern of the front-side redistribution structure 122. In some embodiments, the stacked dies 210 may be coupled to the integrated circuit dies 50A and 50B through the wire bonds 212, the bond pads 204 and 206, the conductive connectors 152, and the front-side redistribution structure 122.

The conductive connectors 152 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 152 may include a conductive material such as solder, copper, aluminum, gold, nickel, silver, palladium, tin, the like, or a combination thereof. In some embodiments, the conductive connectors 152 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 150 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The conductive connectors 152 may be formed to extend through the dielectric layer 136 to contact the metallization pattern 134. Openings are formed through the dielectric layer 136 to expose portions of the metallization pattern 134. The openings may be formed, for example, using laser drilling, etching, or the like. The conductive connectors 152 are formed in the openings. In some embodiments, the conductive connectors 152 comprise flux and are formed in a flux dipping process. In some embodiments, the conductive connectors 152 comprise a conductive paste such as solder paste, silver paste, or the like, and are dispensed in a printing process.

In some embodiments, a solder resist (not shown) is formed on the side of the substrate 202 opposing the stacked dies 210. The conductive connectors 152 may be disposed in openings in the solder resist to be electrically and mechanically coupled to conductive features (e.g., the bond pads 206) in the substrate 202. The solder resist may be used to protect areas of the substrate 202 from external damage.

In some embodiments, the conductive connectors 152 have an epoxy flux (not shown) formed thereon before they are reflowed with at least some of the epoxy portion of the epoxy flux remaining after the second package components 200 are attached to the first package component 100.

In some embodiments, an underfill 220 is formed between the first package component 100 and the second package components 200, surrounding the conductive connectors 152. The underfill may reduce stress and protect the joints resulting from the reflowing of the conductive connectors 152. The underfill may be formed by a capillary flow process after the second package components 200 are attached, or may be formed by a suitable deposition method before the second package components 200 are attached. In embodiments where the epoxy flux is formed, it may act as the underfill. Although the underfill 220 is illustrated as being wholly above the opening 160, in other embodiments, the underfill 220 may extend partially into an upper portion of the opening 160.

As further illustrated by FIGS. 16A and 16B, each first package component 100 may then be mounted to a package substrate 300 using conductive connectors 150. The conductive connectors 150 may be formed to extend through the dielectric layer 108 to contact the metallization pattern 110. Openings are formed through the dielectric layer 108 to expose portions of the metallization pattern 110. The openings may be formed, for example, using laser drilling, etching, or the like. The conductive connectors 150 are formed in the openings. In some embodiments, the conductive connectors 150 comprise flux and are formed in a flux dipping process. In some embodiments, the conductive connectors 150 comprise a conductive paste such as solder paste, silver paste, or the like, and are dispensed in a printing process. In some embodiments, the conductive connectors 150 are formed of a similar material using a similar process as the conductive connectors 152.

The package substrate 300 includes a substrate core 302 and bond pads 304 over the substrate core 302. The substrate core 302 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 302 may be an SOI substrate. Generally, an SOI substrate includes a layer of a semiconductor material such as epitaxial silicon, germanium, silicon germanium, SOI, SGOI, or combinations thereof. The substrate core 302 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 302.

The substrate core 302 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 302 may also include metallization layers and vias (not shown), with the bond pads 304 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 302 is substantially free of active and passive devices.

The package substrate 300 may further include external connectors 310 on under bump metallization (UBMs) 312. Conductive connectors 310 are formed on the UBMs 312. The conductive connectors 310 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 310 may include a conductive material such as solder, copper, aluminum, gold, nickel, silver, palladium, tin, the like, or a combination thereof. In some embodiments, the conductive connectors 310 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 310 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The conductive connectors 310 may be used to attach the package substrate 300 to another package component, such as a printed circuit board (PCB), mother board, another package substrate or the like.

In some embodiments, the conductive connectors 150 are reflowed to attach the first package component 100 to the bond pads 304. The conductive connectors 150 electrically and/or physically couple the package substrate 300, including metallization layers in the substrate core 302, to the first package component 100. In some embodiments, a solder resist 306 is formed on the substrate core 302. The conductive connectors 150 may be disposed in openings in the solder resist 306 to be electrically and mechanically coupled to the bond pads 304. The solder resist 306 may be used to protect areas of the substrate 202 from external damage.

The conductive connectors 150 may have an epoxy flux (not shown) formed thereon before they are reflowed with at least some of the epoxy portion of the epoxy flux remaining after the first package component 100 is attached to the package substrate 300. This remaining epoxy portion may act as an underfill to reduce stress and protect the joints resulting from reflowing the conductive connectors 150. In some embodiments, an underfill 308 may be formed between the first package component 100 and the package substrate 300 and surrounding the conductive connectors 150. The underfill 308 may be formed by a capillary flow process after the first package component 100 is attached or may be formed by a suitable deposition method before the first package component 100 is attached.

In some embodiments, passive devices (e.g., surface mount devices (SMDs), not shown) may also be attached to the first package component 100 (e.g., to the UBMs 138) or to the package substrate 300 (e.g., to the bond pads 304). For example, the passive devices may be bonded to a same surface of the first package component 100 or the package substrate 300 as the conductive connectors 150. The passive devices may be attached to the package component 100 prior to mounting the first package component 100 on the package substrate 300, or may be attached to the package substrate 300 prior to or after mounting the first package component 100 on the package substrate 300.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Thus, a completed semiconductor package 400 comprising a first package component 100, a second package component 200, and a package substrate 300 is provided. The first package component 100 comprises integrated circuit dies 50 that are electrically connected to each other by fan-out structures, specifically, the redistribution structures 122 and 106. The first package component 100 may comprise one or more openings 160 disposed therein, which help facilitate the transfer of heat away from the integrated circuit dies 50 in the first package component by increasing a number of heat dissipation surfaces in the first package component 100. For example, the sidewalls of the openings 160 may provide additional heat dissipation surfaces in the first package component 100. The openings 160 may extend completely through the first package component 100 as illustrated by FIG. 16A, or the openings 160 may extend only partially through the first package component 100. As a result, reliability in the semiconductor package 400 may be improved.

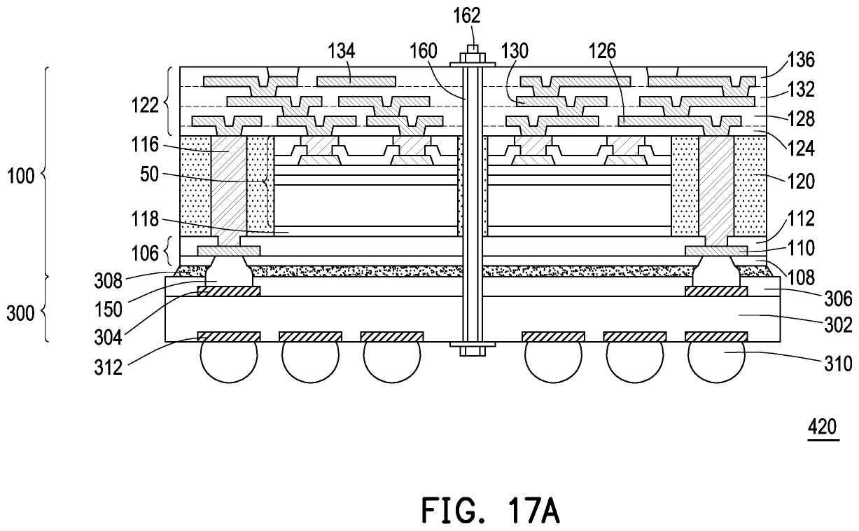

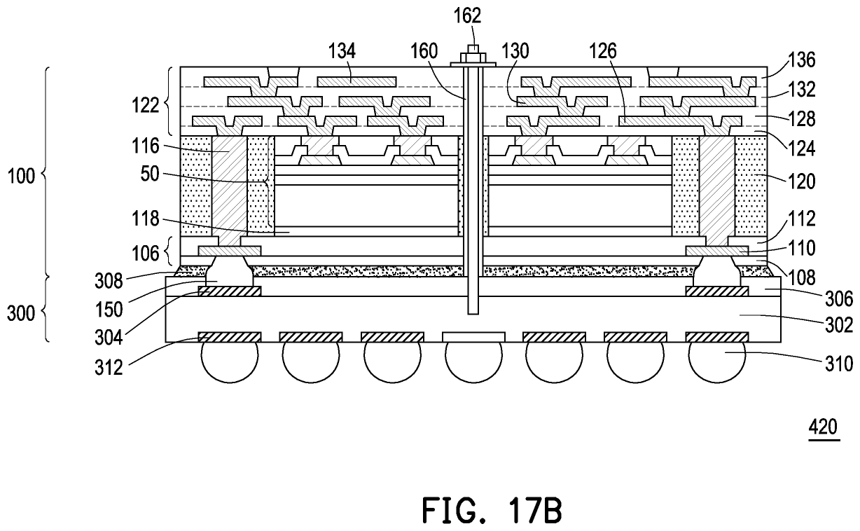

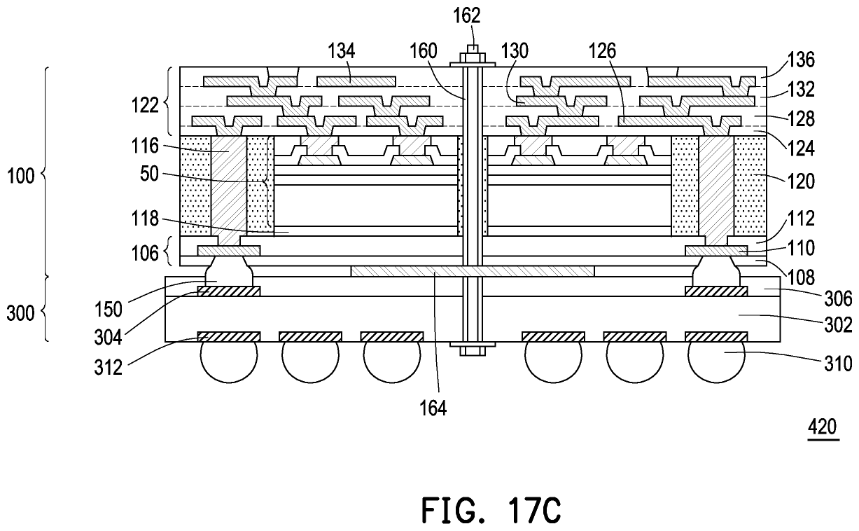

In some embodiments, the openings 160 may facilitate process integration by allowing additional features to be inserted in the openings 160. For example, FIGS. 17A through 17C illustrate cross-sectional views of semiconductor packages 420 according to some embodiments. The semiconductor packages 420 may be substantially similar to the semiconductor package 400 where like reference numerals indicate like elements formed by like processes unless otherwise noted. FIGS. 17A through 17C correspond to the embodiments of FIG. 15A where the opening 160 extends completely through the first package component 100. It should be understood that the description of FIGS. 17A through 17C may be applied to any of the embodiments of FIGS. 15C through 15T described above.

As illustrated in FIGS. 17A, 17B, and 17C, a brace 162 may be placed in the openings 160 to improve the structural integrity of the semiconductor packages 420. Further, to accommodate the placement of the brace 162, the second package components 200 may be omitted from above the first package components 100 in the semiconductor packages 420. In some embodiments, the brace 162 may extend completely through the first package component 100 and the package substrate 300 as illustrated by FIGS. 17A and 17C. In such embodiments, one or more openings may be formed through the package substrate 300, and the first package component 100 may be placed such that the openings 160 are aligned with the openings in the package substrate 300. The metal brace 162 may then be inserted through the openings 160 and the openings in the package substrate 300. Further, an optional horizontal, metal bar 164 may be disposed between the first package component 100 and the package substrate 300 for additional stability, and the brace 162 may extend through the metal bar 164 as illustrated by FIG. 17C. In still other embodiments the brace 162 may extend only partially through the package substrate 300 as illustrated by FIG. 17B. In such embodiments, the brace 162 may be directly inserted into the package substrate 300 without the prior formation of an opening.

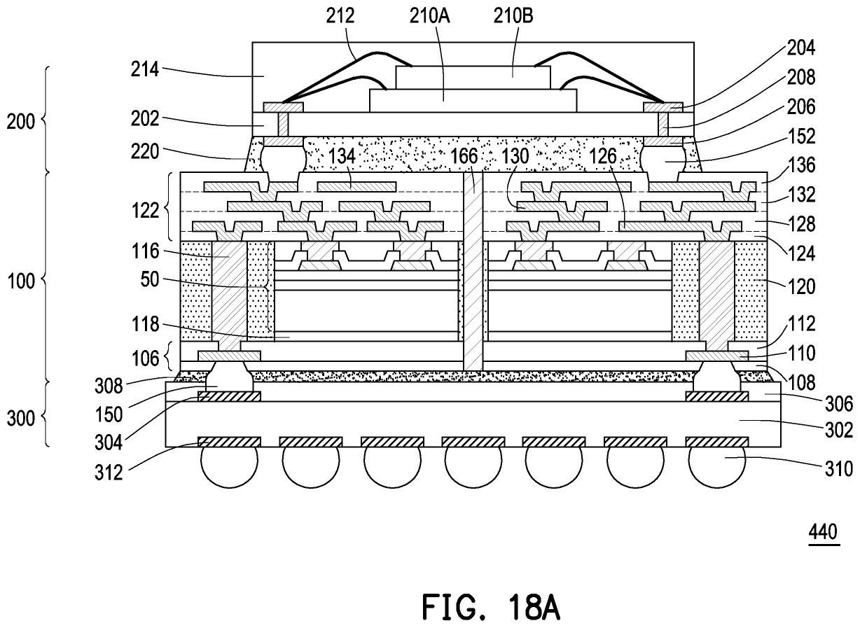

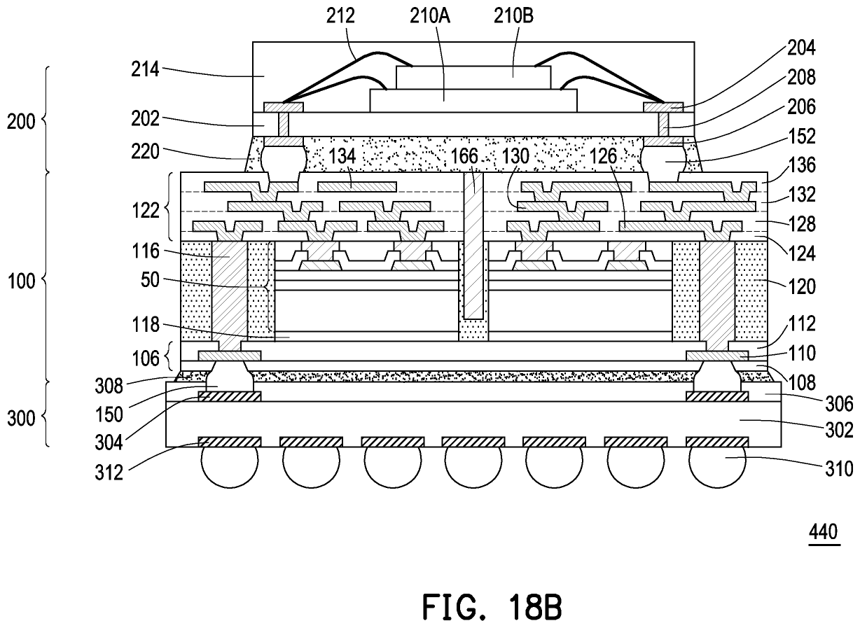

In some embodiments, the openings 160 may facilitate process integration by allowing additional features to be inserted in the openings 160. As another example, FIGS. 18A and 18B illustrate cross-sectional views of semiconductor packages 440 according to some embodiments. The semiconductor packages 440 may be substantially similar to the semiconductor package 400 where like reference numerals indicate like elements formed by like processes unless otherwise noted. FIG. 18A corresponds to the embodiments of FIG. 15A where the openings 160 extend completely through the first package component 100, and FIG. 18B corresponds to the embodiments of FIG. 15B where the openings 160 extend partially through the first package component 100. It should be understood that the description of FIGS. 18A and 18B may be applied to any of the embodiments of FIGS. 15C through 15T described above. In FIGS. 18A and 18B, a package component 166 may be inserted in one or more of the openings 160. The package component 166 may be a high thermal conductivity material/component (e.g., comprising copper, aluminum nitride, heating pipes, cooling pipes, or the like), an EMI shielding material/components (e.g., comprising copper, aluminum, or the like), combinations thereof, or the like. The package component 166 may be formed by plating a conductive material in the openings 160, by adhering a pre-formed package component 166 into the openings 160, or the like. By incorporating additional package components, package performance may be improved. Additionally, the package components may be easily incorporated in the packages 440 through the presence of the openings 160. As a result, the openings 160 may advantageously improve process integration in the packages 440.

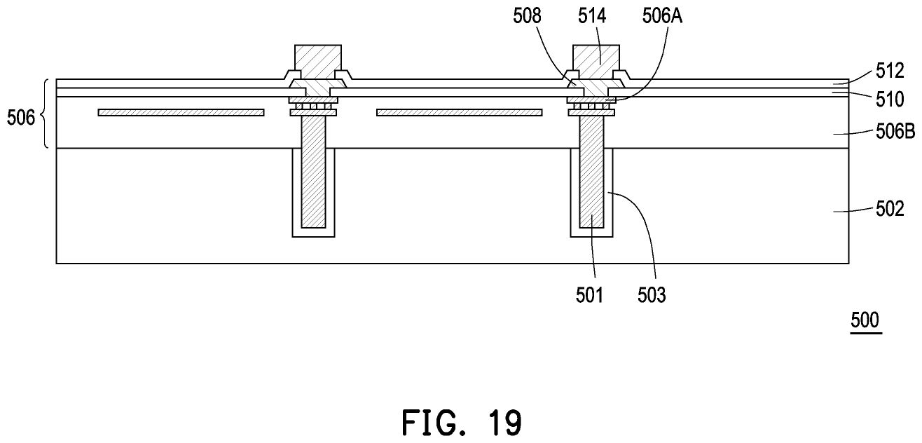

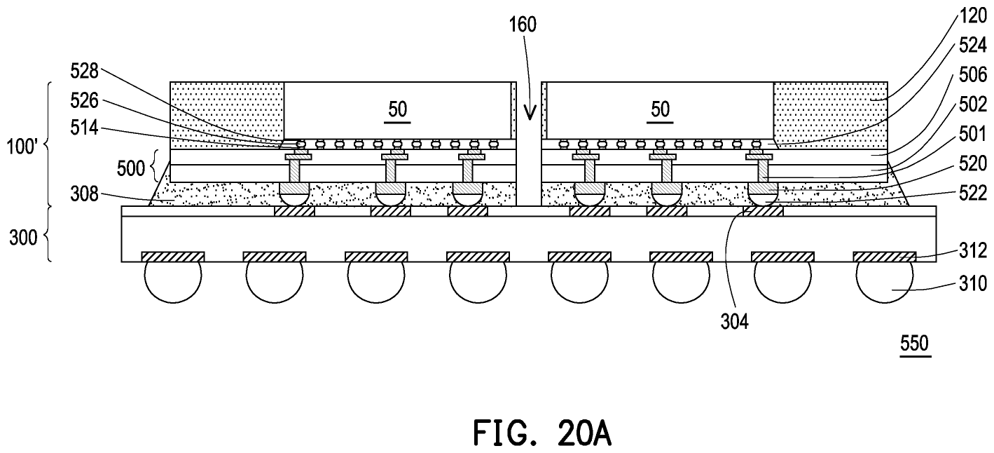

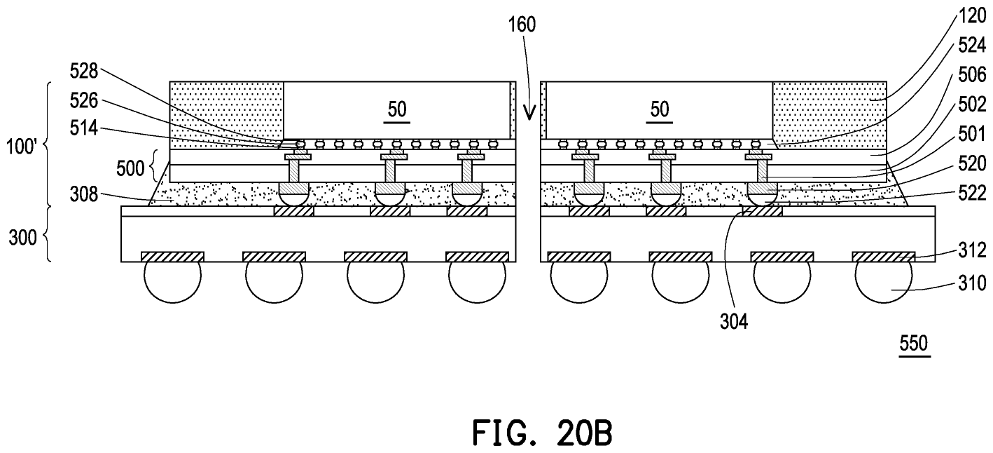

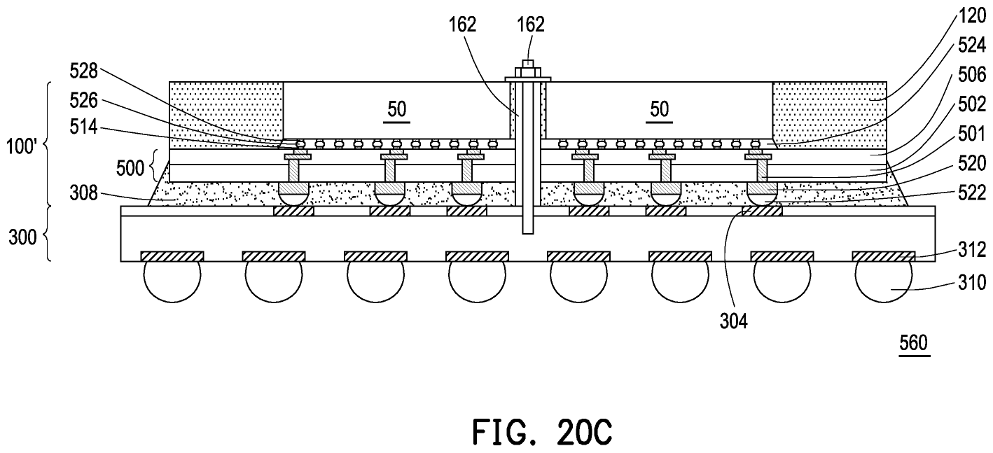

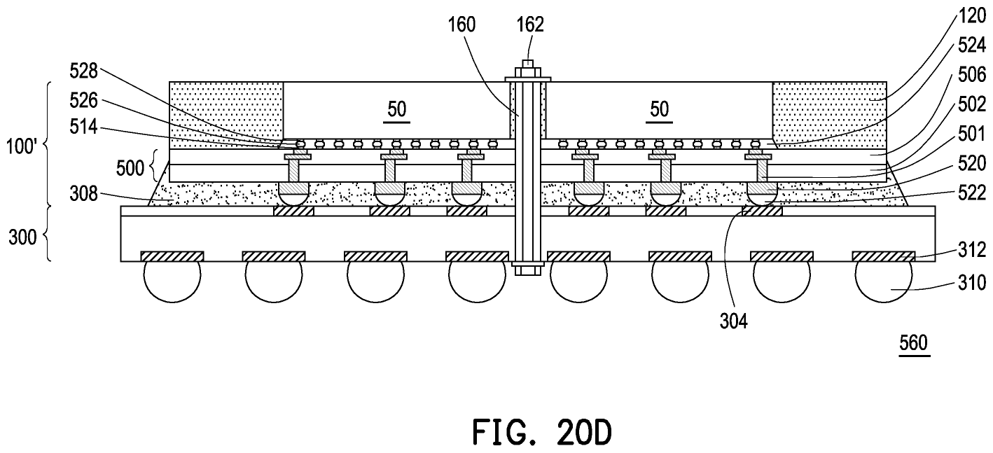

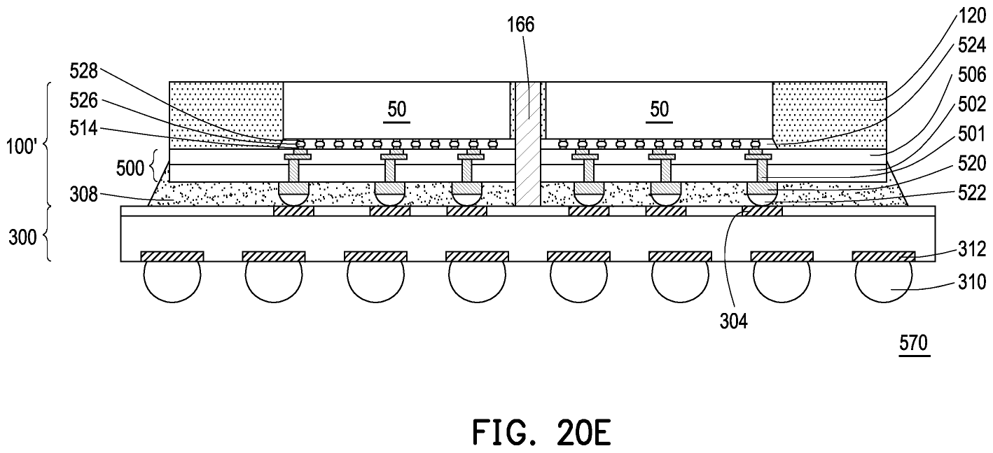

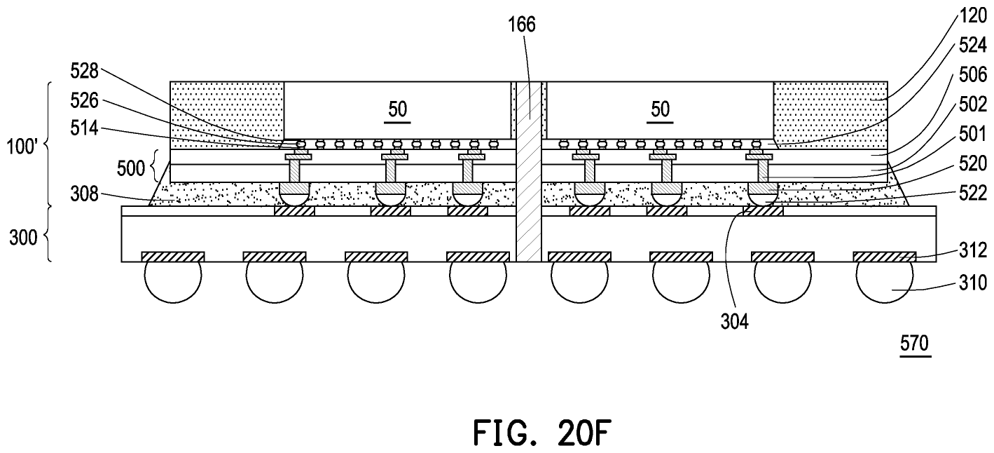

Although FIGS. 1 through 18B illustrate the first package component 100 as having a particular configuration (e.g., as an integrated fan-out package), other configurations are also possible. For example, FIGS. 19 through 20F illustrate a first package component 100′ according to some embodiments where the fan-out structure used to connect integrated circuit dies is an interposer. The first package component 100′ may be incorporated with other package components (e.g., the package substrate 300) to provide a semiconductor package 550, 560, or 570 according to some embodiments. Unless otherwise noted, the packages 550, 560, and 570 may be substantially similar to the packages 400, 420, and 440, respectively, where like reference numerals indicate like elements formed by like processes. However, in the packages 550, 560, and 570, the first package component 100′ has a different configuration than the package component of the packages 400, 420, and 440. Specifically, the package component 100′ comprises integrated circuit dies 50 that are bonded to and electrically interconnected by an interposer 500, which is then bonded to a package substrate 300 in a chip-on-wafer-on-substrate (CoWoS) configuration.

FIG. 19 illustrates an interposer 500 prior to the bonding of any integrated circuit dies according to some embodiments. The interposer 500 may be formed as part of a larger wafer. The interposer 500 may be processed according to applicable manufacturing processes to form integrated circuits in the interposer 500. For example, the interposer 500 may include a semiconductor substrate 502, such as silicon, doped or undoped, or an active layer of a semiconductor-on-insulator (SOI) substrate. The semiconductor substrate 502 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Active and/or passive devices, such as transistors, diodes, capacitors, resistors, inductors, etc., may be formed in and/or on the semiconductor substrate 502. In some embodiments, the interposer 500 is free of any active devices, and only passive devices are formed in and/or on the semiconductor substrate 502. In other embodiments, the interposer 500 may be free of both active and passive devices.

The devices may be interconnected by an interconnect structure 506 comprising, for example, metallization patterns 506A in one or more dielectric layers 506B (also referred to as insulating material layers 506B) on the semiconductor substrate 502. The dielectric layers 506B may be formed of dielectric materials that are deposited by CVD processes and patterned using damascene processes (e.g., single damascene processes, dual damascene processes, or the like). As an example of a damascene process, a dielectric layer 506B may be deposited, and openings may be patterned in the dielectric layer 506B (e.g., with photolithography and/or etching). Subsequently, the openings in the dielectric layer 506B may be filled with a conductive material, and excess conductive material may be removed through a planarization process (e.g., a chemical mechanical polish (CMP) or the like) to form a metallization pattern 506A. The interconnect structures 506 electrically connect the devices on the substrate 502 to form one or more integrated circuits. Although FIG. 19 illustrates the interconnect structure 506 as having a specific number of layers of metallization patterns 506A, embodiments contemplate the interconnect structure 506 having any number of metallization patterns layers.

The interposer 500 further includes through vias 501, which may be electrically connected to the metallization patterns 506A in the interconnect structure 506. The through vias 501 may comprise a conductive material (e.g., copper, or the like) and may extend from a metallization pattern 506A into the substrate 502. One or more insulating barrier layers 503 may be formed around at least portions of the through vias 501 in the substrates 502. The insulating barrier layers 503 may comprise, for example, silicon oxide, silicon nitride, silicon oxynitride, or the like, and may be used to physically and electrically isolate the through vias 501 from each other and the substrate 502. In subsequent processing steps, the substrate 502 may be thinned to expose the through vias 501 (see FIGS. 20A through 20F). After thinning, the through vias 501 provide electrical connection from a back side of the substrate 502 to a front side of the substrate 502. In various embodiments, the backside of the substrate 502 may refer to a side of the substrate 502 opposite to the devices and the interconnect structure 506 while the front side of the substrate 502 may refer to a side of the substrate 502 on which the devices and the interconnect structure 506 are disposed.

In an embodiment, the interposer 500 further comprises contact pads 508, which allow connections to be made to the interconnect structure 506 and the devices on the substrate 502. The contact pads 508 may comprise copper, aluminum (e.g., 28K aluminum), or another conductive material. The contact pads 508 are electrically connected to the metallization patterns 506A of the interconnect structure 506. One or more passivation films may be disposed on the interconnect structure 506, and the contact pads 508. For example, the interconnect structure 506 may include passivation films 510 and 512. The passivation films 510 and 512 may each comprise an inorganic material, such as silicon oxide, silicon oxynitride, silicon nitride, or the like. In some embodiments, the materials of the passivation films 510 and 512 may be the same or different from each other. Further, the materials of the passivation films 510 and 512 may be the same or different from the materials of the dielectric layers 506B. In some embodiments, the contact pads 508 extend over and cover edges of the passivation film 510, and the passivation film 512 extends over and covers edges of the contact pads 508.

UBMs 514 are formed for external connection to one or more integrated circuit dies. The UBMs 514 have bump portions on and extending along the major surface of the passivation film 512, and have via portions extending through the passivation film 512 to physically and electrically couple the contact pads 508. As a result, the UBMs 514 are electrically coupled to the metallization patterns 506A and the through vias 501. The UBMs 514 may be formed of the same material and process as the metallization patterns 126 described above.

The interposer 500 may be formed as part of a larger wafer (e.g., connected to other interposers 500). In some embodiments, the interposers 500 may be singulated from each other after packaging. Subsequently, as illustrated by the embodiments of FIGS. 20A through 20F, integrated circuit dies 50 are attached to the interposer 500. The integrated circuit dies 50 may be attached to a front side of the interposer 500 such that the interconnect structure 506 is disposed between the semiconductor substrate 502 and the integrated circuit dies 50.

In the illustrated embodiment, the integrated circuit dies 50 are attached to the interposer 500 with solder bonds, such as conductive connectors 526 on UBMs 528 of the integrated circuit dies 50. The integrated circuit dies 50 may be placed on the interposer 500 using, e.g., a pick-and-place tool. The conductive connectors 526 may be formed a similar material and a similar method as described above with respect to the conductive connectors 152 described above (see FIGS. 16A and 16B), and the UBMs 528 may be formed a similar material and a similar method as described above with respect to the UBMs 514. Attaching the integrated circuit dies 50 to the interposer 500 may include placing the integrated circuit dies 50 on the interposer 500 and reflowing the conductive connectors 526. The conductive connectors 526 form joints between UBMs 514 of the interposer 500 and the UBMs 528 of the integrated circuit dies 50, electrically connecting the interposer 500 to the integrated circuit dies 50.

As also illustrated in FIGS. 20A through 20F, an underfill 524 may be formed around the conductive connectors 526, and between the interposer 500 and the integrated circuit dies 50. The underfill 524 may reduce stress and protect the joints resulting from the reflowing of the conductive connectors 526. The underfill 524 may be formed a similar material and a similar method as described above with respect to the as the underfill 308. The encapsulant 120 may be then formed around the integrated circuit dies 50 and the underfill 524.

Subsequently, a backside the substrate 502 is thinned to expose the through vias 501. Exposure of the through vias 501 may be accomplished by a thinning process, such as a grinding process, a chemical-mechanical polish (CMP), an etch-back, combinations thereof, or the like. In some embodiments (not separately illustrated), the thinning process for exposing the through vias 501 includes a CMP, and the through vias 501 protrude at the back-side of the interposer 500 as a result of dishing that occurs during the CMP. In such embodiments, an insulating layer (not separately illustrated) may optionally be formed on the back surface of the substrate 502, surrounding the protruding portions of the through vias 501. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. After the substrate 502 is thinned, the exposed surfaces of the through vias 501 and the insulating layer (if present) or the substrate 502 are coplanar (within process variations) such that they are level with one another, and are exposed at the back-side of the interposer 500.

In FIG. 16, a backside redistribution structure (not illustrated) and UBMs 520 are formed on the exposed surfaces of the through vias 501 and the substrate 502. The backside redistribution structure may be formed of similar materials and processes as the interconnect structure 506 or the redistribution structure 122 (see FIGS. 16A and 16B), described above. For example, the backside redistribution structure may comprise one or more metallization layers in insulting materials. Further the UBMs 520 may be formed of similar materials and processes as the UBMs 542, described above.

Conductive connectors 522 are formed on the UBMs 520. The conductive connectors 522 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 522 may include a conductive material such as solder, copper, aluminum, gold, nickel, silver, palladium, tin, the like, or a combination thereof. In some embodiments, the conductive connectors 522 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 522 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

A singulation process is performed by cutting along scribe line regions of the interposer 500. The singulation process may include sawing, dicing, or the like. For example, the singulation process can include sawing the encapsulant 120, the interconnect structure 506, and the substrate 502. The singulation process singulates each package 100′ from adjacent packages 100′. The singulation process forms interposers 500 from the singulated portions of the interposer wafer. As a result of the singulation process, the outer sidewalls of the interposer 500 (including the interconnect structure 506, the passivation layers 510/512, and substrate 502) and the encapsulant 120 are laterally coterminous (within process variations). Further the encapsulant 120 may completely surround the integrated circuit dies 50 in a plan view.

The package 100′ will be attached to a package substrate 300, by flip chip bonding, with the conductive connectors 522. The underfill 308 may be formed around the conductive connectors 522 between the first package component 100′ and the package substrate 300, and the openings 160 may be formed through the package 100′, thus completing formation of the integrated circuit package. The openings 160 may have any of the configurations and/or be formed by any of the processes described above with respect to FIGS. 15A through 15T. FIGS. 20A and 20B illustrate embodiment completed semiconductor packages 550 with the openings 160 according to some embodiments. In some embodiments as illustrated by FIG. 20A, the openings 160 may extend through the first package component 100 and the underfill 308 to a top surface of the package substrate 300. In some embodiments as illustrated by FIG. 20B, the openings 160 may also extend through the package substrate 300 in addition to the first package component 100. FIGS. 20C and 20D illustrate embodiment completed semiconductor packages 560 with the openings 160 according to some embodiments. In package 560, a brace 162 may be placed in the openings 160 for additional structural support. FIG. 20C illustrates an embodiment where the openings 160/brace 162 extend to the package substrate 300, and FIG. 20D illustrates an embodiment where the openings 160/brace 162 extend through the package substrate 300. FIGS. 20E and 20F illustrate embodiment completed semiconductor packages 570 with the openings 160 according to some embodiments. In package 570, a package component 166 (e.g., a high thermal conductivity material/component, an EMI shielding material/components combinations thereof, or the like) may be placed in the openings 160. FIG. 20E illustrates an embodiment where the openings 160/package component 166 extend to the package substrate 300, and FIG. 20F illustrates an embodiment where the openings 160/package component 166 extend through the package substrate 300.

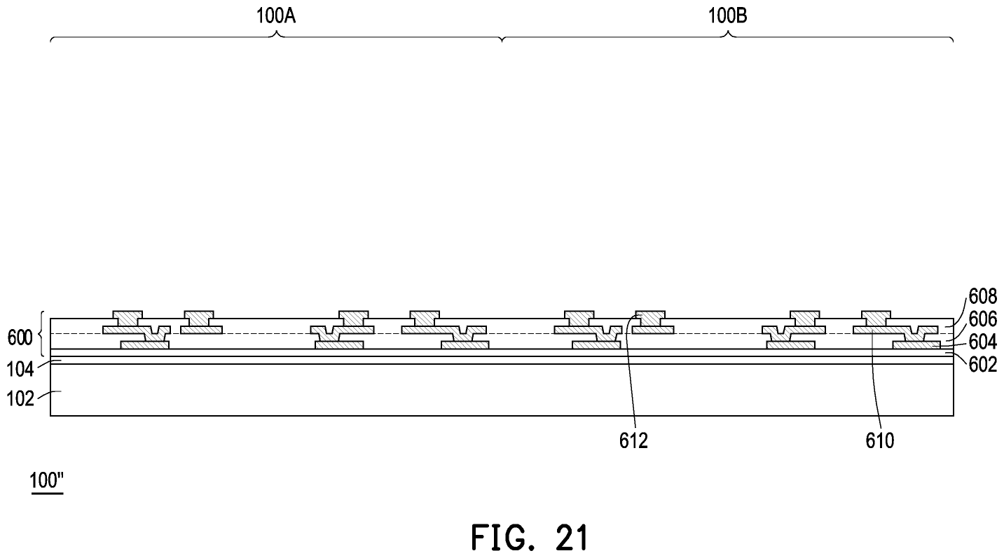

FIGS. 19 through 20F illustrate the integrated circuit dies 50 being electrically interconnected by the interposer 500. In other embodiments, the interposer 500 may be replaced with another fan-out structure. For example, FIGS. 21 through 23F illustrate a first package component 100″ according to some embodiments where the fan-out structure is a redistribution structure 600. The first package component 100″ may be incorporated with other package components (e.g., the package substrate 300) to provide a semiconductor package 650, 660, or 670 according to some embodiments. Unless otherwise noted, the packages 650, 660, and 670 may be substantially similar to the packages 550, 560, and 570, respectively, where like reference numerals indicate like elements formed by like processes. However, in the packages, 650, 660, and 670, the first package component 100″ has a different configuration than the package component of the packages 550, 560, and 570. Specifically, the package component 100″ comprises integrated circuit dies that are bonded to and electrically interconnected by a redistribution structure 600, which is then bonded to a package substrate 300 in a chip-on-wafer-on-substrate-redistribution (CoWoS-R) configuration.

Referring first to FIG. 21, a redistribution structure 600 may be formed on the release layer 104 over the carrier substrate 102. The redistribution structure 600 may comprise metallization patterns 604, 610 and 612 as well as dielectric layers 602, 606, and 608. The redistribution structure may be formed of a similar material and process as the redistribution structure 122 described above (see FIGS. 16A and 16B). Specifically, each of the metallization patterns 604, 610 and 612 may be made of a similar material and process as the metallization pattern 126, and each of the dielectric layers 602, 606, and 608 may be made of a similar material and process as the dielectric layer 124. In some embodiments, the metallization pattern 612 may provide UBMs for the redistribution structure 600.

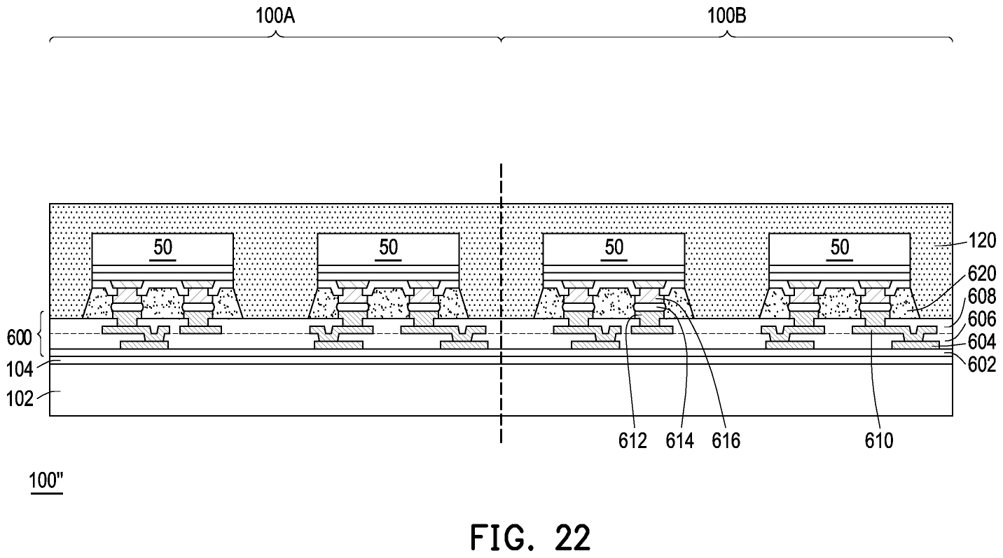

In FIG. 22, the integrated circuit dies 50 are attached to the redistribution structure 600 with solder bonds, such as conductive connectors 614 on the UBMs 616 of the integrated circuit dies 50. The integrated circuit dies 50 may be placed on the redistribution structure 600 using, e.g., a pick-and-place tool. The conductive connectors 614 may be formed a similar material and a similar method as described above with respect to the conductive connectors 152 (see FIGS. 16A and 16B) and the UBMs 616 may be formed a similar material and a similar method as described above with respect to the UBMs 514. Attaching the integrated circuit dies 50 to the redistribution structure 600 may include placing the integrated circuit dies 50 on the redistribution structure 600 and reflowing the conductive connectors 614. The conductive connectors 614 form joints between UBMs 616 of the redistribution structure 600 and the UBMs 616 of the integrated circuit dies 50, electrically connecting the redistribution structure 600 to the integrated circuit dies 50.

An underfill 620 may be formed around the conductive connectors 614, and between the redistribution structure 600 and the integrated circuit dies 50. The underfill 620 may reduce stress and protect the joints resulting from the reflowing of the conductive connectors 614. The underfill 620 may be formed a similar material and a similar method as described above with respect to the underfill 308. The encapsulant 120 may be then formed around the integrated circuit dies 50 and the underfill 620 over the redistribution structure 600.

A singulation process is performed by cutting along scribe line regions of the redistribution structure 600. The singulation process may include sawing, dicing, or the like. For example, the singulation process can include sawing the encapsulant 120 and the redistribution structure 600. The singulation process singulates each package 100″ from adjacent packages 100″. The singulation process forms redistribution structure 600 from the singulated portions of the wafer. As a result of the singulation process, the outer sidewalls of the redistribution structure 600 and the encapsulant 120 are laterally coterminous (within process variations). Further the encapsulant 120 may completely surround the integrated circuit dies 50 in a plan view.

Conductive connectors 622 and UBMs 624 are formed extending through the dielectric layer 602 to contact the metallization pattern 604. Openings are formed through the dielectric layer 602 to expose portions of the metallization pattern 604. The openings may be formed, for example, using laser drilling, etching, or the like. The conductive connectors 622/the UBMs 625 are formed in the openings. The conductive connectors 622/the UBMs 624 may be formed a similar material and a similar method as described above with respect to the conductive connectors 150/the UBMS 514 described above (see FIGS. 16A and 16B).

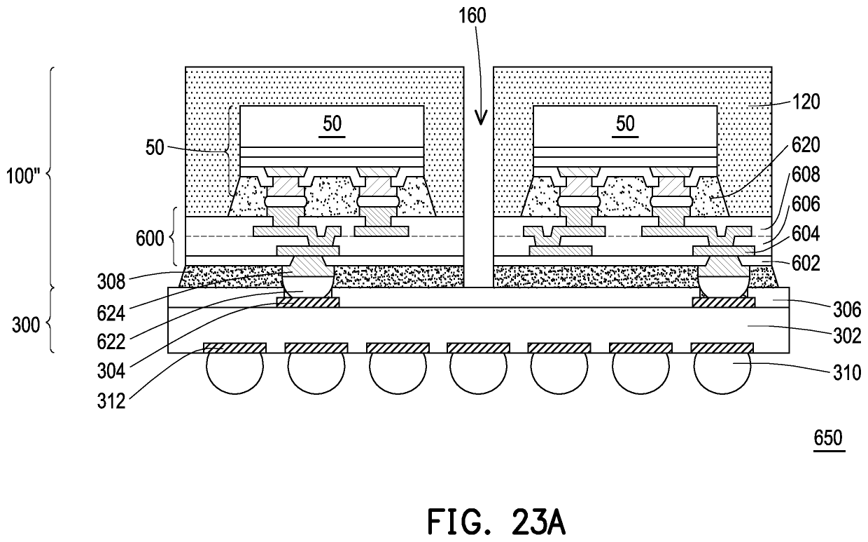

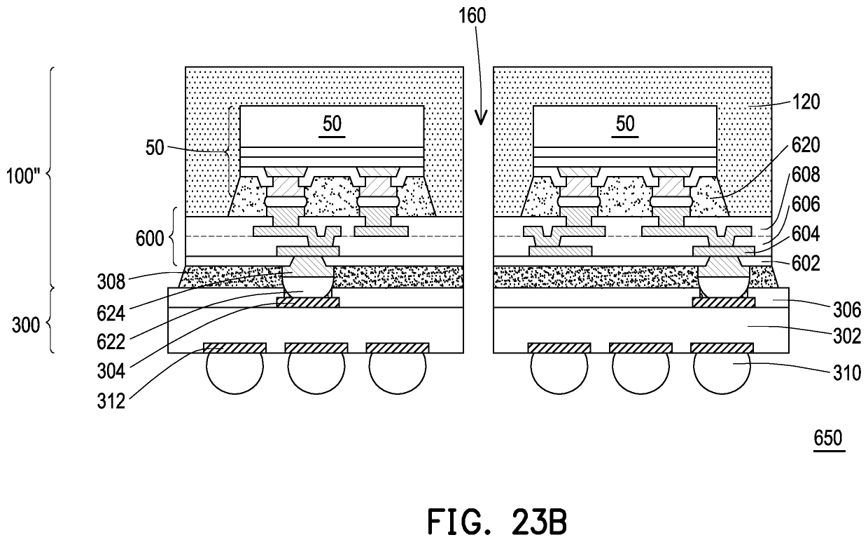

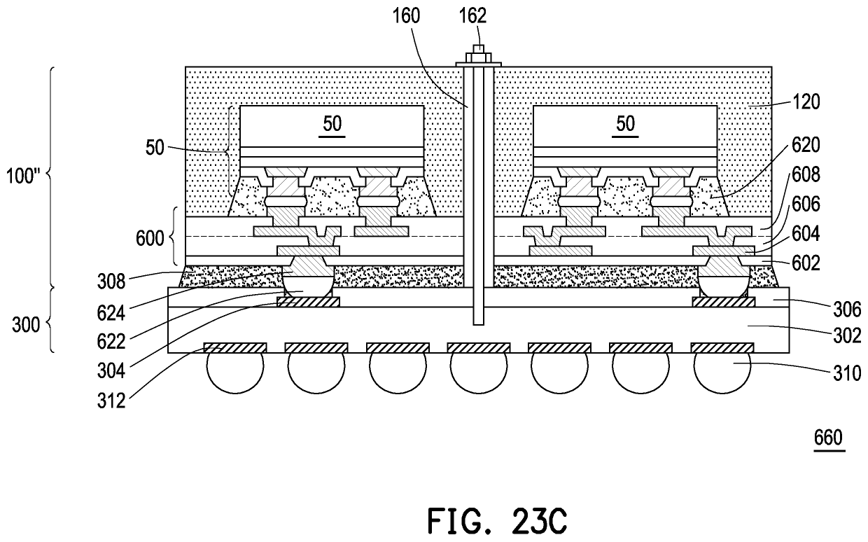

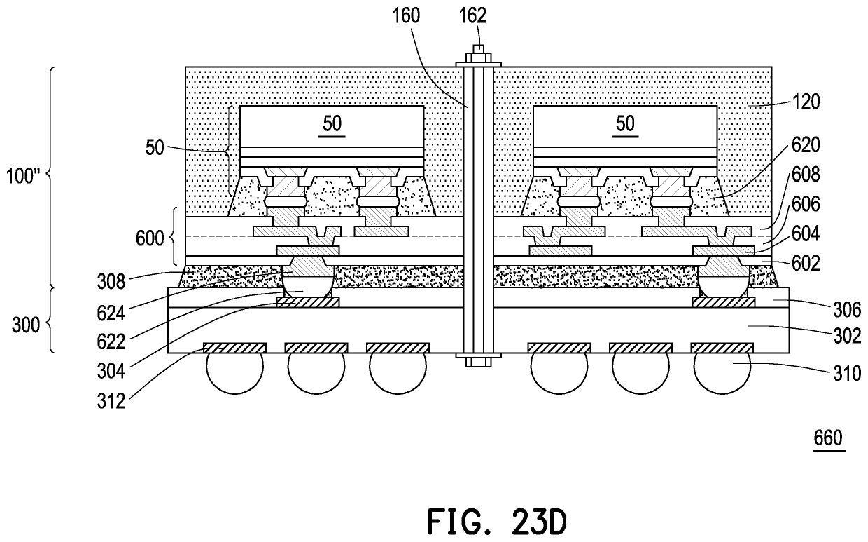

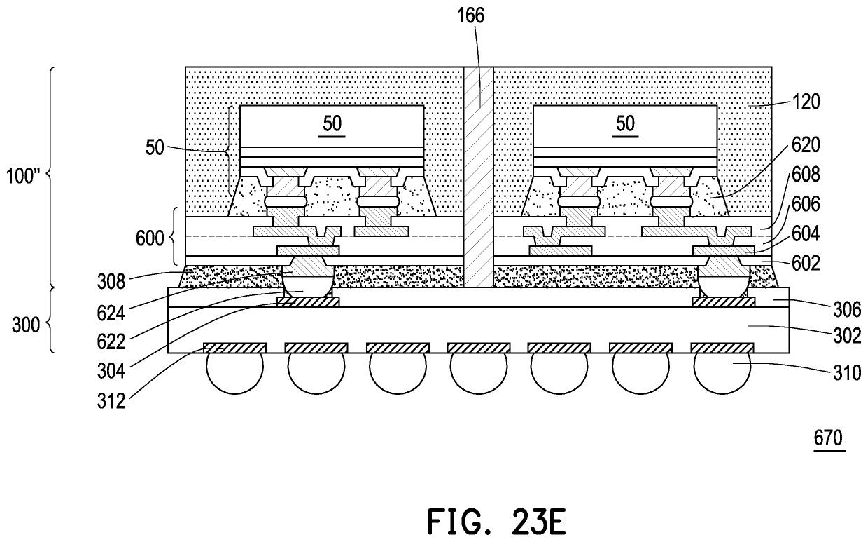

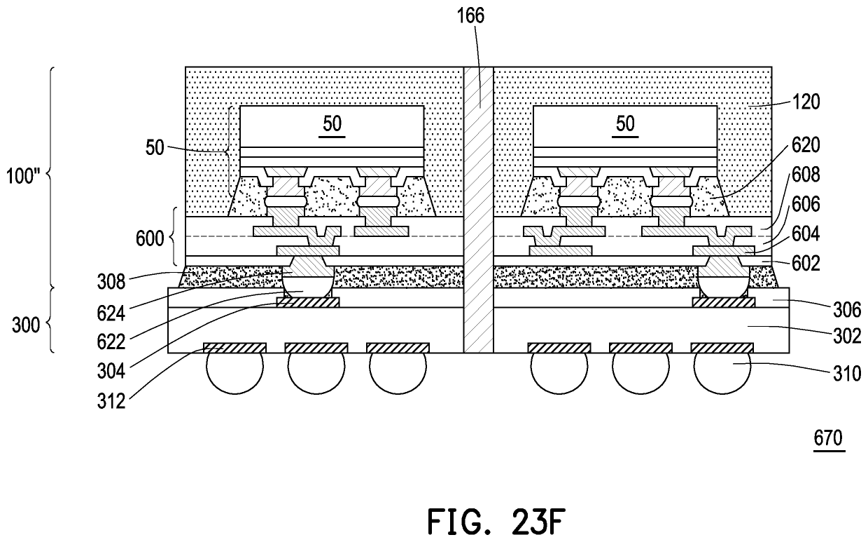

The first package component 100″ is then attached to the package substrate 300, by flip chip bonding, with the conductive connectors 622. The underfill 308 may be formed around the conductive connectors 622 between the first package component 100″ and the package substrate 300, and the openings 160 may be formed through the package 100″, thus completing formation of the integrated circuit package. The openings 160 may have any of the configurations and/or be formed by any of the processes described above with respect to FIGS. 15A through 15T. FIGS. 23A and 23B illustrate embodiment completed semiconductor packages 650 with the openings 160 according to some embodiments. In some embodiments as illustrated by FIG. 23A, the openings 160 may extend through the first package component 100″ and the underfill 308 to a top surface of the package substrate 300. In some embodiments as illustrated by FIG. 23B, the openings 160 may also extend through the package substrate 300 in addition to the first package component 100″. FIGS. 23C and 23D illustrate embodiment completed semiconductor packages 660 with the openings 160 according to some embodiments. In packages 660, a brace 162 may be placed in the openings 160 for additional structural support. FIG. 23C illustrates an embodiment where the openings 160/brace 162 extend to the package substrate 300, and FIG. 23D illustrates an embodiment where the openings 160/brace 162 extend through the package substrate 300. FIGS. 23E and 23F illustrate embodiment completed semiconductor packages 670 with the openings 160 according to some embodiments. In package 670, a package component 166 (e.g., a high thermal conductivity material/component, an EMI shielding material/components combinations thereof, or the like) may be placed in the openings 160. FIG. 23E illustrates an embodiment where the openings 160/package component 166 extend to the package substrate 300, and FIG. 23F illustrates an embodiment where the openings 160/package component 166 extend through the package substrate 300.

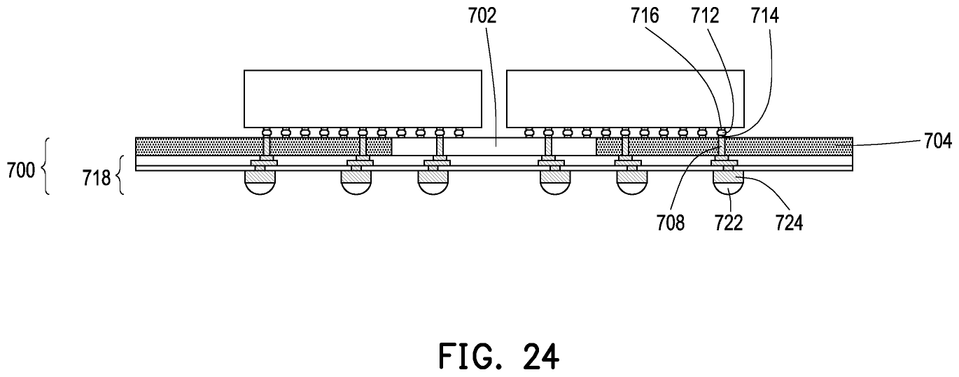

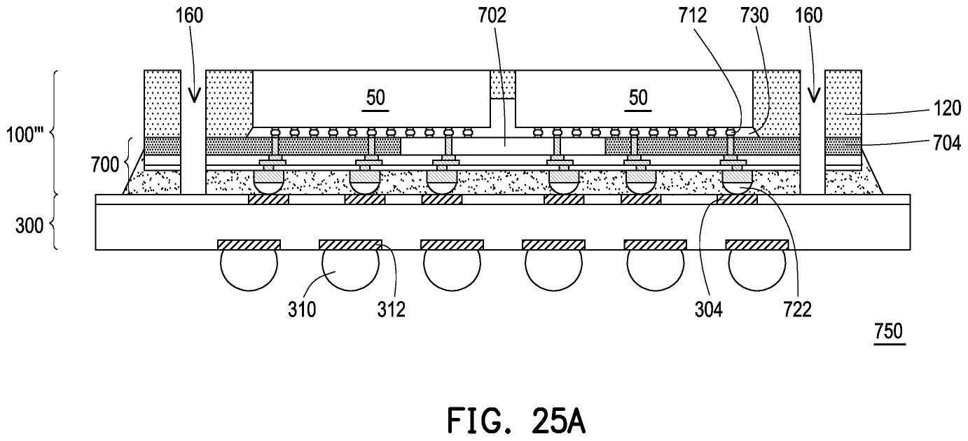

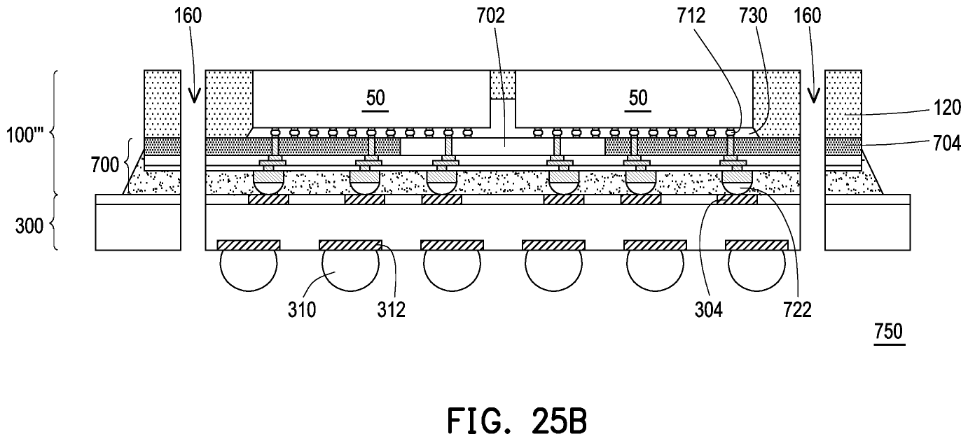

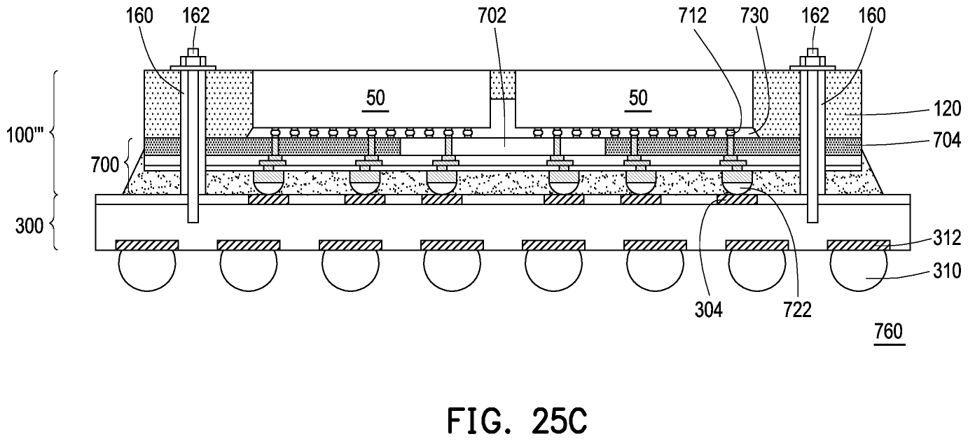

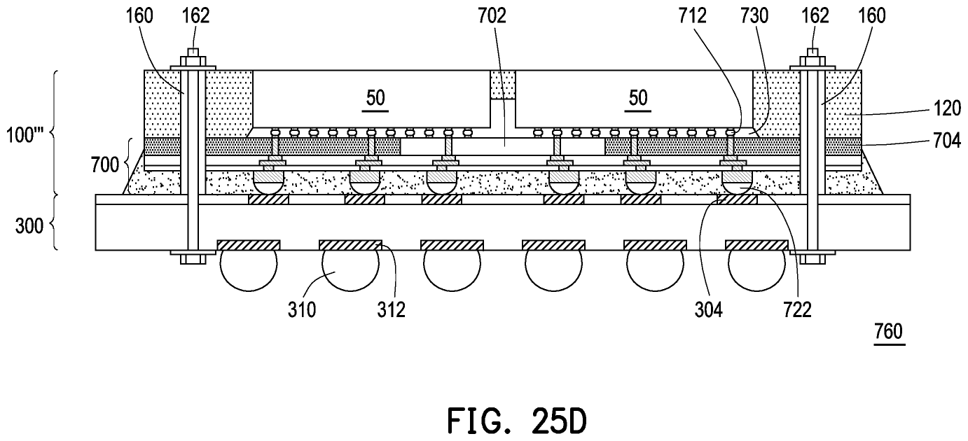

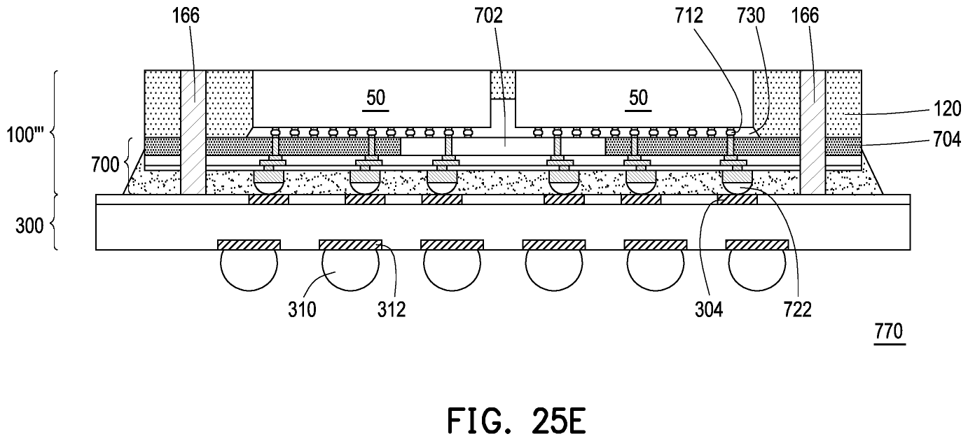

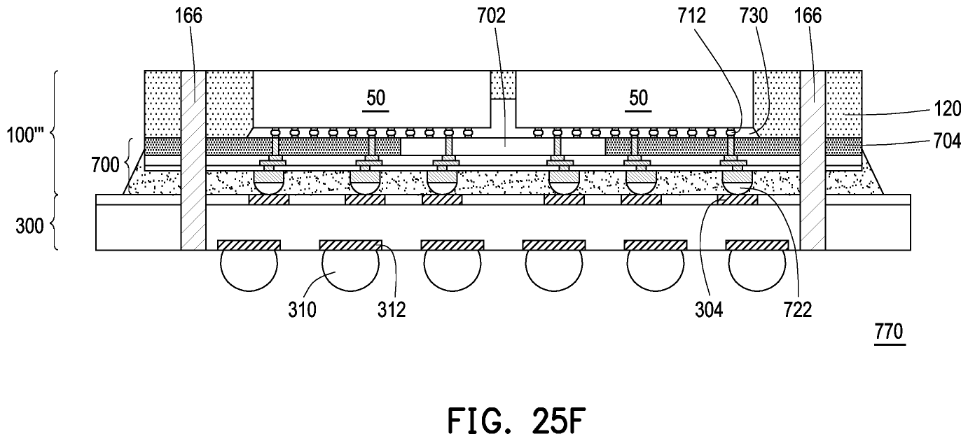

FIGS. 19 through 23F illustrate the integrated circuit dies 50 being electrically interconnected by the interposer 500 or the redistribution structure 600. In other embodiments, the interposer 500/redistribution structure may be replaced with another fan-out structure. For example, FIGS. 24 through 25F illustrate a first package component 100″′ according to some embodiments where the fan-out structure includes an LSI die (sometimes referred to as a bridge die). The first package component 100″′ may be incorporated with other package components (e.g., the package substrate 300) to provide a semiconductor package 750, 760, or 770 according to some embodiments. Unless otherwise noted, the packages 750, 760, and 770 may be substantially similar to the packages 550, 560, and 570, respectively, where like reference numerals indicate like elements formed by like processes. However, in the packages, 750, 760, and 770, the first package component 100′′ has a different configuration than the package component of the packages 550, 560, and 570. Specifically, the package component 100″′ comprises integrated circuit dies that are bonded to and electrically interconnected by an LSI die, which is then bonded to a package substrate 300 in a chip-on-wafer-on-substrate-less silicon substrate (CoWoS-L) configuration.

Referring first to FIG. 24, a fan-out structure 700 is illustrated. The fan-out structure 700 may comprise an LSI die 702 that is encapsulated in an encapsulant 704 with through vias 706. The LSI die 702 may be formed of a similar material using a similar process as the integrated circuit dies 50. However, the LSI die 702 may be free of any active devices and may further include TSVs 708, which provide electrical connection between a back side and a frontside of a silicon substrate of the LSI die 702. The encapsulant 704 and the through vias 706 may be formed of a similar material using a similar process as the encapsulant 120 and the through vias 116, respectively (see FIGS. 16A and 16B). The LSI dies 702 may be electrically connected to a redistribution structure 718, which may be formed of a similar material using a similar process as the front-side redistribution structure 122 described above (see FIGS. 16A and 16B). The redistribution structure 718 may further include UBMs 724 and conductive connectors 722. In some embodiments, the conductive connectors 722 may be formed of a similar material using a similar process as the conductive connectors 152 (see FIGS. 16A and 16B), and the UBMs 724 may be formed of a similar material using a similar process as the UBMs 514.

In FIG. 22, the integrated circuit dies 50 are attached to the fan-out structure 700 with solder bonds, such as conductive connectors 712 on the UBMs 716 of the integrated circuit dies 50. The integrated circuit dies 50 may be placed on the fan-out structure 700 using, e.g., a pick-and-place tool. The conductive connectors 712 may be formed a similar material and a similar method as described above with respect to the conductive connectors 152 (see FIGS. 16A and 16B) and the UBMs 716 may be formed a similar material and a similar method as described above with respect to the UBMs 514. Attaching the integrated circuit dies 50 to the fan-out structure 700 may include placing the integrated circuit dies 50 on the fan-out structure 700 and reflowing the conductive connectors 712. The conductive connectors 712 form joints between UBMs 714 of the fan-out structure 700 and the UBMs 716 of the integrated circuit dies 50, electrically connecting the fan-out structure 700 to the integrated circuit dies 50. The LSI die 702 may include circuits that provide routing between the integrated circuit dies 50, and the through vias 706/redistribution structure 718 may provide addition routing from the integrated circuit dies/the LSI die 702 to the conductive connectors 722. The UBMs 716 may be formed of a similar material and a similar method as described above with respect to the UBMs 514, and the UBMs 716 may be formed directly on the through vias 706 in the encapsulant 704 as well as the TSVs 708 of the LSI die 702.

Next in FIGS. 25A through 25E, an underfill 730 may be formed around the conductive connectors 712. The underfill 730 may reduce stress and protect the joints resulting from the reflowing of the conductive connectors 712. The underfill 730 may be formed a similar material and a similar method as described above with respect to the underfill 308. The encapsulant 120 may be then formed around the integrated circuit dies 50 and the underfill 730 over the LSI die 702 and the encapsulant 704.

A singulation process is performed by cutting along scribe line regions of the fan-out structure 700. The singulation process may include sawing, dicing, or the like. For example, the singulation process can include sawing the encapsulant 120 and the fan-out structure 700. The singulation process singulates each package 100″′ from adjacent packages 100′″. The singulation process forms fan-out structure 700 from the singulated portions of the wafer. As a result of the singulation process, the outer sidewalls of the fan-out structure 700 and the encapsulant 120 are laterally coterminous (within process variations). Further the encapsulant 120 may completely surround the integrated circuit dies 50 in a plan view.

The first package component 100′″ is then attached to the package substrate 300, by flip chip bonding, with the conductive connectors 722. The underfill 308 may be formed around the conductive connectors 722 between the first package component 100′″ and the package substrate 300, and the openings 160 may be formed through the package 100″′, thus completing formation of the integrated circuit package. The openings 160 may have any of the configurations and/or be formed by any of the processes described above with respect to FIGS. 15A through 15T. In some embodiments, the openings 160 may be placed around a periphery of the integrated circuit dies 50 to avoid the LSI die 702. FIGS. 25A and 25B illustrate embodiment completed semiconductor packages 750 with the openings 160 according to some embodiments. In some embodiments as illustrated by FIG. 25A, the openings 160 may extend through the first package component 100″′ and the underfill 308 to a top surface of the package substrate 300. In some embodiments as illustrated by FIG. 25B, the openings 160 may also extend through the package substrate 300 in addition to the first package component 100″′. FIGS. 25C and 25D illustrate embodiment completed semiconductor packages 760 with the openings 160 according to some embodiments. In packages 760, a brace 162 may be placed in the openings 160 for additional structural support. FIG. 25C illustrates an embodiment where the openings 160/brace 162 extend to the package substrate 300, and FIG. 25D illustrates an embodiment where the openings 160/brace 162 extend through the package substrate 300. FIGS. 25E and 25F illustrate embodiment completed semiconductor packages 770 with the openings 160 according to some embodiments. In package 770, a package component 166 (e.g., a high thermal conductivity material/component, an EMI shielding material/components combinations thereof, or the like) may be placed in the openings 160. FIG. 25E illustrates an embodiment where the openings 160/package component 166 extend to the package substrate 300, and FIG. 25F illustrates an embodiment where the openings 160/package component 166 extend through the package substrate 300.

In accordance with some embodiments, one or more integrated circuit dies are electrically connected by a fan-out structure (e.g., a redistribution structure, an interposer, a local silicon interconnect (LSI), or the like), and the integrated circuit dies may be encapsulated for further packaging with other package components (e.g., a package substrate or the like). One or more openings may be formed in the molding compound and/or the fan-out structure. The inclusion of the openings may facilitate thermal dissipation of heat away from the semiconductor dies through the openings. As another example, the openings may facilitate the insertion of one or more advantageous components, such as a thermal dissipation feature, electromagnetic interference (EMI) shields, structural support (e.g., mechanical braces), or the like. As a result, improved package performance and/or manufacturing ease may be achieved.

In some embodiments, a semiconductor package includes a first package component comprising: an integrated circuit die; an encapsulant surrounding the integrated circuit die; and a fan-out structure electrically connected to the integrated circuit die, wherein a first opening extends completely through the fan-out structure and at least partially through the encapsulant in a cross-sectional view, and wherein the encapsulant at least completely surrounds the first opening in a top-down view. The semiconductor package further includes a package substrate bonded to the first package component. Optionally, in some embodiments, the first opening extends completely through the first package component. Optionally, in some embodiments, the first opening extends completely through the package substrate. Optionally, in some embodiments, a second opening extends completely through the fan-out structure and at least partially through the encapsulant in the cross-sectional view, wherein the encapsulant only partially surrounds the second opening in the top-down view. Optionally, in some embodiments, the semiconductor package further includes a brace in the opening, wherein the brace extends at least partially into the package substrate. Optionally, in some embodiments, the mechanical brace extends completely through the package substrate. Optionally, in some embodiments, the fan-out structure comprises a redistribution structure. Optionally, in some embodiments, the fan-out structure comprises an interposer. Optionally, in some embodiments, the fan-out structure comprises a local silicon interconnect (LSI) die. Optionally, in some embodiments, the semiconductor package further includes through vias extending through the encapsulant.

In some embodiments, a semiconductor package includes a first package component comprising: a first integrated circuit die; a second integrated circuit die; an encapsulant surrounding the first integrated circuit die and the second integrated circuit die; a fan-out structure electrically connecting the first integrated circuit die to the second integrated circuit die; and a conductive package component extending through the fan-out structure into the encapsulant, wherein the conductive package component is a high thermal conductivity component, an EMI shielding component, or a combination thereof. The semiconductor package further includes a package substrate bonded to the first package component. Optionally, in some embodiments, the conductive package component comprises copper or aluminum. Optionally, in some embodiments, the conductive package component only extends partially through the encapsulant. Optionally, in some embodiments, the conductive package component only extends completely through the encapsulant.

In some embodiments, a method of manufacturing a semiconductor package includes forming a first package component, forming the first package component comprising: encapsulating an integrated circuit die in a molding compound; forming a redistribution structure over the molding compound and the integrated circuit die, wherein the redistribution structure is electrically connected to the integrated circuit die; after forming the redistribution structure, patterning an opening extending through the redistribution structure into the encapsulant. The method further includes bonding a package substrate to the first package component. Optionally, in some embodiments, patterning the opening comprises laser machining, mechanical drilling/routing, plasma etching/bombardment, or chemical etching. Optionally, in some embodiments, the method further includes placing a mechanical brace in the opening, the mechanical brace securing the first package component to the package substrate. Optionally, in some embodiments, the method further includes placing a package component in the opening, wherein the package component is a high thermal conductivity component, an EMI shielding component, or a combination thereof. Optionally, in some embodiments, after patterning the opening, a portion of the molding compound remains disposed directly under the opening. Optionally, in some embodiments, patterning the opening comprises patterning the opening through the molding compound.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package comprising:
a first package component comprising:
an integrated circuit die;
an encapsulant surrounding the integrated circuit die; and
a fan-out structure electrically connected to the integrated circuit die, wherein a first opening extends completely through the fan-out structure and at least partially through the encapsulant in a cross-sectional view, and wherein the encapsulant at least completely surrounds the first opening in a top-down view; and
a package substrate bonded to the first package component.

2. The semiconductor package of claim 1, wherein the first opening extends completely through the first package component.

3. The semiconductor package of claim 1, wherein the first opening extends completely through the package substrate.

4. The semiconductor package of claim 1, wherein a second opening extends completely through the fan-out structure and at least partially through the encapsulant in the cross-sectional view, and wherein the encapsulant only partially surrounds the second opening in the top-down view.

5. The semiconductor package of claim 1 further comprises a mechanical brace in the opening, wherein the mechanical brace extends at least partially into the package substrate.

6. The semiconductor package of claim 1, wherein the mechanical brace extends completely through the package substrate.

7. The semiconductor package of claim 1, wherein the fan-out structure comprises a redistribution structure.

8. The semiconductor package of claim 1, wherein the fan-out structure comprises an interposer.

9. The semiconductor package of claim 1, wherein the fan-out structure comprises a local silicon interconnect (LSI) die.

10. The semiconductor package of claim 1 further comprising through vias extending through the encapsulant.

11. A semiconductor package comprising:
a first package component comprising:
a first integrated circuit die;
a second integrated circuit die;
an encapsulant surrounding the first integrated circuit die and the second integrated circuit die;
a fan-out structure electrically connecting the first integrated circuit die to the second integrated circuit die; and
a conductive package component extending through the fan-out structure into the encapsulant, wherein the conductive package component is a high thermal conductivity component, an EMI shielding component, or a combination thereof; and
a package substrate bonded to the first package component.

12. The semiconductor package of claim 11, wherein the conductive package component comprises copper or aluminum.

13. The semiconductor package of claim 11, wherein the conductive package component only extends partially through the encapsulant.

14. The semiconductor package of claim 11, wherein the conductive package component only extends completely through the encapsulant.

15. A method of manufacturing a semiconductor package, the method comprising:
forming a first package component, forming the first package component comprising:
encapsulating an integrated circuit die in a molding compound;
forming a redistribution structure over the molding compound and the integrated circuit die, wherein the redistribution structure is electrically connected to the integrated circuit die;
after forming the redistribution structure, patterning an opening extending through the redistribution structure into the encapsulant; and
bonding a package substrate to the first package component.

16. The method according to claim 15, wherein patterning the opening comprises laser machining, mechanical drilling/routing, plasma etching/bombardment, or chemical etching.

17. The method according to claim 15 further comprising placing a mechanical brace in the opening, the mechanical brace securing the first package component to the package substrate.

18. The method according to claim 15 further comprising placing a package component in the opening, wherein the package component is a high thermal conductivity component, an EMI shielding component, or a combination thereof.

19. The method according to claim 15, wherein after patterning the opening, a portion of the molding compound remains disposed directly under the opening.

20. The method according to claim 15, wherein patterning the opening comprises patterning the opening through the molding compound.
